(19) United States
(12) Patent Application Publication
(10) Pub. No.: US 2006/0240631 A1
(43) Pub. Date: Oct. 26, 2006

(54) Method for manufacturing a solid-state image capturing device and electric information device

(75) Inventor: Takayuki Kawasaki, Osaka (JP)

Correspondence Address: EDWARDS & ANGELL, LLP, P.O. BOX 55874, BOSTON, MA, 02205, US

(73) Assignee: Sharp Kabushiki Kaisha, Osaka (JP)

(21) Appl. No.: 11/404,538

(22) Filed: Apr. 16, 2006

(30) Foreign Application Priority Data
Apr. 22, 2005 (JP) 2005-125592

(51) Int. Cl. H01L 21/336

(52) U.S. Cl. 438/302; 438/305; 438/306

(57) ABSTRACT

A method for manufacturing a solid-state image capturing device, in which at least one electric charge detection section detects each respective one of a plurality of electric charges photoelectrically converted and accumulated at photoelectric conversion sections provided on a semiconductor substrate, each electric charge detection section being shared by a plurality of the photoelectric conversion sections, the method including: an impurity region forming step of forming an impurity region on a surface of each photoelectric conversion section of the plurality of photoelectric conversion sections by performing an ion implantation from at least one direction crossing an arrangement direction of the plurality of photoelectric conversion sections, the at least one direction having a predetermined inclination angle with respect to a normal line perpendicular to the surface.

This Nonprovisional application claims priority under 35 U.S.C. §119(a) on Patent Application No. 2005-125592 filed in Japan on Apr. 22, 2005, the entire contents of which are hereby incorporated by reference.

### BACKGROUND OF THE INVENTION

1. Field of the Invention

The present invention relates to; a method for manufacturing a solid-state image capturing device in which an electric charge detection section is shared by each plurality of photoelectric conversion sections, the electric charge detection section detecting an amount of electric charges converted from incident light by the photoelectric conversion sections; and an electronic information device (e.g., a camera-equipped cellular phone, a digital-still camera and a digital video camera) using the solid-state image capturing device manufactured by using the manufacturing method.

2. Description of the Related Art

Conventionally, such a solid-state image capturing device reads electric charges generated at a photo diode layer (photoelectric conversion section; electric charge accumulation region) via a reading gate. The amount of the read electric charges is detected by an electric charge detection section (floating diffusion section). In this case, Reference 1 discloses a CMOS-type (complementary metal oxide semiconductor) solid-state image capturing device in which one electric charge detection section is shared by a plurality of photo diodes. Reference 1 will be described with reference to FIGS. 15 to 19.

FIG. 15 is a plan view showing relevant parts of a unit of two pixels in a conventional CMOS-type solid-state image capturing device. The portion (a) of FIG. 16 is a plan view showing each sectional-position of the two pixel sections shown in FIG. 15. The portion (b) of FIG. 16 is a cross-sectional view of the portion (a) of FIG. 16 cut by a line A-A′. The portion (c) of FIG. 16 is a cross-sectional view of the portion (a) of FIG. 16 cut by a line B-B′. FIG. 17 is a plan view showing relevant parts in each step for explaining a method for manufacturing a CMOS-type solid-state image capturing device shown in FIG. 15.

A method for manufacturing a CMOS-type solid-state image capturing device 200 will be described with reference to FIGS. 15 to 17. First, a P-type diffusion layer 202 (P well) is formed on an entire N-type semiconductor substrate 201 by performing an ion implantation (e.g., boron) process and a thermal treatment. Next, a thermal oxidation treatment is selectively performed on the substrate using a pattern 203 as shown in the portion (a) of FIG. 17 in a plan view, in order to separate an active region and an inactive region in an element. As a result, a thick thermal oxidation film is formed on the inactive region side.

Next, a gate silicon oxidation film 204 is formed on a surface (surface of the active region) of the silicon substrate 1 by performing a thermal oxidation treatment at a temperature of 1000 degrees Celsius to 1100 degrees Celsius in an atmosphere of O₂ gas and HCI gas. Thereafter, a multi-layered film, in which, for example, a poli-silicon film and a W (tungsten) film are layered, is formed by performing a CVD/sputtering and the like. A photolithography is performed on the multi-layered film using a pattern as shown in the portion (b) of FIG. 17, and then a dry etching is performed on the resultant film. Thus, a reading gate electrode 205 and a reset gate electrode 206 are formed on a region which will become an N-type impurity diffusion layer 207 corresponding to the pattern 203.

Furthermore, the region of the N-type impurity diffusion layer 207 which will become a photo diode layer (photoelectric conversion section; electric charge accumulation region) is patterned by using a surface P+ layer forming resist pattern 208 as shown in the portion (c) of FIG. 17. Thereafter, an ion implantation (e.g., either phosphorus or arsenic) process and a thermal treatment are performed on the resultant N-type impurity diffusion layer 207. Thus, an oxidation film having a thick inactive layer is formed on a circumference of the N-type impurity diffusion layer 207, which will become a photo diode layer. The side of the N-type impurity diffusion layer 207 on the reading gate electrode 205 side is formed in a manner such that it is self-aligned by the reading gate electrode 205.

Furthermore, the electric charge detection section 209 and a reset drain section 210 are each patterned into a predetermined pattern by using an N+ layer forming pattern 211 as shown in the portion (d) of FIG. 17. Thereafter, an ion implantation (e.g., arsenic) process is performed on the resultant electric charge detection section 209 and a reset drain section 210. The electric charge detection section 209 and the reset drain section 210 are formed in a manner such that they are each self-aligned by each of gate electrodes 205 and 205, the reset gate 206 and the oxidation film having a thick inactive region.

Furthermore, in order to suppress a white defect (luminescent spot defect; bright spot on a total black screen) caused by an energy level occurred at the surface (silicon substrate surface) of the photo diode layer, the photo diode layer is patterned by using the same pattern as the surface P+ layer forming resist pattern 208 as shown in the portion (c) of FIG. 17. An ion implantation (e.g., boron) process and a thermal treatment are performed on the surface of the photodiode layer with an ion implantation direction 212 having a predetermined inclination so as to form a photo diode surface P+ layer 213 as an impurity region at the surface of the photoelectric conversion section.

As described above, the conventional CMOS-type solid-state image capturing device 200 is manufactured.

Herein, the operation, in which electric charges are read from the photo diode (photoelectric conversion section) to the electric charge detection section (floating diffusion section) via a reading gate, will be described with reference to FIG. 18.

FIG. 18 is a view schematically showing potentials formed on each region in a semiconductor substrate so as to correspond to the cross-sectional view of the portion (b) of FIG. 16 cut by the line A-A′.

As shown in FIG. 18, the N-type impurity diffusion layer 207 (photo diode layer) is an electric charge accumulation region as well as a region for electrically converting incident light. Electric charges which are photoelectrically converted are accumulated at the photo diode layer. When a reading voltage is applied to the reading gate electrode 205 with a desired timing, potentials of a substrate region underneath the reading gate electrode 205 are lowered. As a result, the electric charges accumulated at the photo diode layer flow to the electric charge detection section 209 side via the reading gate electrode 205. Electrical potentials corresponding to the amount of the electric charges detected by the electric charge detection section 209 are amplified so as to obtain an image capturing signal.

Herein, a structure, in which an electric charge detection section 209 is shared by each two-pixel section (N-type impurity diffusion layer 207; photo diode layer) arranged in upper and lower positions, will be described.

FIG. 19 is a diagram for explaining the effect resulting from the structure, in which an electric charge detection section 209 is shared by each two-pixel section (N-type impurity diffusion layer 207; photo diode layer) arranged in upper and lower positions as shown in FIG. 15. the portion (a) of FIG. 19 is a plan view showing: a unit of two pixels; and a case where the two pixel sections arranged in the upper and lower positions share the electric charge detection section 209 and the following sections after the electric charge detection section 209. The portion (b) of FIG. 19 is a plan view showing two pixel sections, which shows a case where the electric charge detection section 209 is provided for each pixel.

When the electric charge detection section 209 is shared by a unit of two pixel sections (N-type impurity diffusion layer 207; photo diode layer) via the reading gate electrode 205 of each pixel section as shown in the portion (a) of FIG. 19, the size of a pixel area for each pixel section can be larger than that in the case when an electric charge detection section 209a (or 209b) is provided for each pixel section (N-type impurity diffusion layer 207a or 207b; photo diode layer) via the reading gate electrode 205a (or 205b) of each pixel section as shown in the portion (b) of FIG. 19, thereby sensitivity characteristic to incident light being improved. As for operation of reading the electric charge in this case, a captured image with an excellent quality can be obtained by controlling an electric charge accumulation, a reading and a reset at two pixel sections arranged in the upper and lower positions, with a good timing.

It is known that an operation of reading electric charges from such a photo diode layer (photoelectric conversion section) to the electric charge detection section 209 is subject to a great influence by the state underneath the reading gate electrode 205. The height of a potential barrier underneath the reading gate electrode 205 influences: a reading voltage which is required for completely reading the electric charges accumulated, at the photo diode layer (N-type impurity diffusion layer 207) in which incident light is photoelectrically converted, to the electric charge detection section 209; and the amount of electric charges accumulated at the photodiode layer (N-type impurity diffusion layer 207). Therefore, the state underneath the reading gate electrode 205 influences the characteristic of the entire CMOS-type solid-state image capturing device 200 to a great extent.

The potential barrier underneath the reading gate electrode 205 is controlled by a single P-type diffusion layer 202 (P well) which is an impurity layer under the reading gate electrode 205 or is controlled by introducing an impurity for control in to the P-type diffusion layer 202. However, a photodiode surface P+ layer 213, which is formed in order to suppress a white defect, extends underneath the reading gate electrode 205 by a lateral diffusion due to an ion implantation process and a thermal treatment, thereby the photodiode surface P+ layer 213 influencing the reading characteristic (accumulation characteristic) to a great extent.

The formation of the conventional photo diode surface P+ layer 213 will be described in detail with reference to FIG. 16.

The photo diode surface P+ layer 213 is formed by performing an ion implantation process at a speed having a relatively slow acceleration. An entry direction 212 of an ion beam has approximately 7 degrees of inclination angle with respect to a direction vertical to the plain surface of a substrate wafer. The entry direction 212 of the ion beam is an ion implantation direction going down at an inclined angle with respect to the surface of the two pixel sections arranged in the upper and lower positions. In this case, the entry direction 212 of the ion beam into the pixel section arranged in the upper position and the entry direction 212 of the ion beam into the pixel section arranged in the lower position are different in the portion (b) of FIG. 16 and the portion (c) of FIG. 16 which are cross-sectional views taken from a direction perpendicular to the arrangement direction of each reading gate electrode 205. In other words, in the portion (b) of FIG. 16, the photo diode surface P+ layer 213 is formed so as to substantially extend underneath the gate electrode 205 due to the ion beam into the pixel section arranged in the upper position. In the portion (c) of FIG. 16, the edge of the tip portion of the photo diode surface P+ surface 213 is formed so as to coincide with the edge of the reading gate electrode 205 due to the ion beam into the pixel section arranged in the lower position. That is, as for the pixel section arranged in the lower position as shown in the portion (c) of FIG. 16, the edge of the tip portion of the photo diode surface P+ layer 213 is formed at a position a little bit away from the reading gate electrode 205 due to a shadowing (i.e., ions are not implanted at the edge of the reading gate electrode 205) of the reading gate electrode 205 and is diffused in a lateral direction so as to coincide with the edge (end portion) of the reading gate electrode 205 due to the following thermal treatment.

In contrast, as shown in FIG. 20, Reference 2 forms an N well layer 302 on an entire P-type semiconductor substrate 301 in another conventional CMOS-type solid-state image capturing device 300. A gate silicon oxide film 304 is formed on the surface of the N well layer 302. Thereafter, a reading gate electrode 305 and a reset gate electrode 306 are formed on a substrate where the gate silicon oxide film 304 is formed. Next, an N-type impurity diffusion layer 307 which will become a photo diode layer is formed at a predetermined position by performing an ion implantation processing. Thereafter, an electric charge detection section 309 and a reset drain section 310 are formed, respectively, on the substrate where the N-type impurity diffusion layer 307. Furthermore, an ion implantation process is performed on the surface of the N-type impurity diffusion layer 307. Thereafter, a thermal treatment is performed thereon, and a photo diode surface P+ layer 313 is diffused in a lateral direction so as to be formed as an impurity region at the surface of the photoelectric conversion section. The electric charge detection section 309 is configured by an N-type source 314, a P-type gate 315 and an N-type channel 316.

In this case, the overlap of the N-type impurity diffusion layer 307 and the photo diode surface P+layer 313 is formed with an excellent controllability. Thus, electric charges can be completely transferred, without residual electric charge on the N-type impurity diffusion layer 307, to the electric charge detection section 309 from the N-type impurity diffusion layer 307, thereby suppressing the occurrence of residual image.

[Reference 1] Japanese Laid-Open Publication No. 09-46596

[Reference 2] Japanese Laid-Open Publication No. 11-126893

### SUMMARY OF THE INVENTION

However, with the configuration of the conventional Reference 1, as described above, in the ion implantation process in order to form the photo diode surface P+ layer 213, the photo diode surface P+ layer 213 is formed so as to substantially extend underneath the reading gate electrode 205 due to the ion beam into the pixel section arranged in the upper position as shown in the portion (b) of FIG. 16, and the edge of the tip portion of the photo diode surface P+ layer 213 is formed so as to coincide with the edge of the reading gate electrode 205 due to the ion beam into the pixel section arranged in the lower position as shown in the portion (c) of FIG. 16. A large difference in an element characteristic between the pixel section arranged in the upper position and the pixel section arranged in the lower position occurs due to non-uniformity between each edge of the tip portion of the photo diode surface P+ layer 213. The co-existence of elements having different characteristics in each line on an image capturing screen influences the image capturing screen to a great extent. As a result, the Reference 1 had a problem of display defect, such as a horizontal streak on a display screen.

In contrast, in the conventional Reference 2, as described above, there is no description about the ion implantation direction in order to form the photo diode surface P+ layer 313. The photodiode surface P+ layer 313 is formed in a manner such that it is diffused in a lateral direction so as to extend underneath the reading gate electrode 305 due to a thermal treatment. Thus, in Reference 2, in order to suppress the occurrence of residual image by completely transferring the electric charges to the electric charge detection section 309 without residual electric charge, the optimal overlap of the N-type impurity diffusion layer 307 and the photodiode surface P+ layer 313 is intended to be formed. However, since the edge of the tip portion of the photo diode surface P+ layer 313 extends underneath the reading gate electrode 305 due to the thermal treatment, the position of the edge of the tip portion of the photo diode surface P+ layer 313 underneath the reading gate electrode 305 in each edge diffusion instance is non-uniform. As a result, a difference between the positions of the edges of the tip portion of the photo diode surface P+ layer 313 underneath the reading gate electrode 305 occurs. Thus, a similar problem to Reference 1 occurs.

The present invention is intended to solve the aforementioned problems. The objective of the present invention is to provide a method for manufacturing a solid-image capturing device capable of making the reading characteristic of each pixel section uniform and an electronic information device (e.g., a camera-equipped cellular phone) using the solid-state image capturing device manufactured by using the manufacturing method.

A method for manufacturing a solid-state image capturing device according to the present invention, in which at least one electric charge detection section detects each respective one of a plurality of electric charges photoelectrically converted and accumulated at photoelectric conversion sections provided on a semiconductor substrate, each electric charge detection section being shared by a plurality of the photoelectric conversion sections, the method including: an impurity region forming step of forming an impurity region on a surface of each photoelectric conversion section of the plurality of photoelectric conversion sections by performing an ion implantation from at least one direction crossing an arrangement direction of the plurality of photoelectric conversion sections, the at least one direction having a predetermined inclination angle with respect to a normal line perpendicular to the surface, thereby the objective above described being achieved.

In a method for manufacturing a solid-state image capturing device according to the present invention, an angle between the arrangement direction and the at least one direction which crosses the arrangement direction is 90 degrees.

Furthermore, in a method for manufacturing a solid-state image capturing device according to the present invention, an angle between the arrangement direction and the at least one direction which crosses the arrangement direction is 45 degrees.

Furthermore, in a method for manufacturing a solid-state image capturing device according to the present invention, the at least one direction which crosses the arrangement direction is a plurality of directions.

Furthermore, in a method for manufacturing a solid-state image capturing device according to the present invention, the plurality of photoelectric conversion sections is two pixel sections, and the at least one ion implantation direction is either a direction perpendicular to the arrangement direction in a plan view or a direction opposite to the direction perpendicular to the arrangement direction in the plan view.

Furthermore, in a method for manufacturing a solid-state image capturing device according to the present invention, the plurality of photoelectric conversion sections is four pixel sections, and the at least one ion implantation direction is two directions, the two directions being a direction perpendicular to the arrangement direction in a plan view and a direction opposite to the direction perpendicular to the arrangement direction in the plan view.

Furthermore, in a method for manufacturing a solid-state image capturing device according to the present invention, the plurality of photoelectric conversion sections is two pixel sections, and the at least one ion implantation direction is two directions, the two directions forming an angle of 45 degrees with respect to the direction perpendicular to the arrangement direction in a plan view.

Furthermore, in a method for manufacturing a solid-state image capturing device according to the present invention, the plurality of photoelectric conversion sections is four pixel sections, and the at least one ion implantation direction is four directions in total, two directions of the four directions forming an angle of 45 degrees with respect to the direction perpendicular to the arrangement direction in a plan view, and the other two directions of the four directions being provided opposite to the two directions.

A method for manufacturing a solid-state image capturing device according to the present invention, in which at least one electric charge detection section detects each respective one of a plurality of electric charges photoelectrically converted and accumulated at photoelectric conversion sections provided on a semiconductor substrate, each electric charge detection section being shared by a plurality of photoelectric conversion sections, the method including: an impurity region forming step of forming an impurity region on each surface of the plurality of photoelectric conversion sections by performing an ion implantation from two directions, one of the two directions being one arrangement direction of the plurality of photoelectric conversion sections and the other of the two directions being opposite to the one arrangement direction, the two directions having a predetermined inclination angle with respect to a normal line perpendicular to the surface, thereby the objective described above being achieved.

Furthermore, a method for manufacturing a solid-state image capturing device according to the present invention includes a gate electrode forming step of forming a gate electrode on a semiconductor substrate which is of a conductivity-type, for reading a plurality of electric charges from the photoelectric conversion section to the electric charge detection section; a photoelectric conversion section forming step of forming an electric charge accumulation region of a first conductivity-type as the photoelectric conversion section; and an electric charge detection section forming step of forming the electric charge detection section of the first conductivity-type, the electric charge detection section being adjacent to the photoelectric conversion section with a gate electrode interposed therebetween; wherein the impurity region forming step includes forming the impurity region on the surface of the photoelectric conversion section, the impurity region being formed to be of a second conductivity-type.

Furthermore, in a method for manufacturing a solid-state image capturing device according to the present invention, the at least one ion implantation direction is chosen such that an edge of a tip portion of the impurity region is formed in a manner such that it extends underneath a lower end portion of the gate electrode on the photoelectric conversion section side.

Furthermore, in a method for manufacturing a solid-state image capturing device according to the present invention, the at least one ion implantation direction is chosen such that it forms a predetermined angle with respect to the end portion of the gate electrode on the photoelectric conversion section side, and the impurity region is formed away from the end portion of the gate electrode by a distance depending on the predetermined angle.

Furthermore, in a method for manufacturing a solid-state image capturing device according to the present invention, the angle α is 90 degrees or 45 degrees.

Furthermore, in a method for manufacturing a solid-state image capturing device according to the present invention, an end face of the gate electrode on the photoelectric conversion section side has a tapered shape widening toward the bottom when viewed in a cross-sectional view, and the gate electrode is tapered at the predetermined inclination angle such that the impurity region at the surface is not formed away by the predetermined inclination angle from the end portion of the gate electrode on the photoelectric conversion section side.

Furthermore, in a method for manufacturing a solid-state image capturing device according to the present invention, the at least one ion implantation direction is chosen to cross a longitudinal direction of the gate electrode with respect to the longitudinal direction from the photoelectric conversion section side and forms an angle α with respect to the longitudinal direction of the gate electrode.

Furthermore, in a method for manufacturing a solid-state image capturing device according to the present invention, the plurality of electronic conversion sections having the electric charge detection section shared thereby is two pixel sections arranged in upper and lower positions or arranged in left and right positions in a plan view.

Furthermore, in a method for manufacturing a solid-state image capturing device according to the present invention, the electric charge detection section is shared by the two pixel sections via the reading gate electrode of each pixel section, the electric charge detection section being provided on an imaginary bisecting line perpendicular to an arrangement direction of the two pixel sections.

Furthermore, in a method for manufacturing a solid-state image capturing device according to the present invention, the plurality of photoelectric conversion sections having the electric charge detection section shared thereby is four pixel sections.

Furthermore, in a method for manufacturing a solid-state image capturing device according to the present invention, the four pixel sections include two sets of two pixel sections arranged in upper and lower positions or arranged in left and right positions in a plan view, and the electric charge detection section shared by the four pixel sections is provided at a central position of the four pixel sections via the reading gate electrode of each pixel section.

Furthermore, in a method for manufacturing a solid-state image capturing device according to the present invention, the predetermined inclination angle is an angle at which a channeling does not occur within a crystal lattice of the semiconductor substrate.

Furthermore, in a method for manufacturing a solid-state image capturing device according to the present invention, the semiconductor substrate is a silicon semiconductor substrate, and the crystal lattice is a silicon crystal lattice.

Furthermore, in a method for manufacturing a solid-state image capturing device according to the present invention, the predetermined inclination angle is 7 degrees ±0.5 degrees.

Furthermore, in a method for manufacturing a solid-state image capturing device according to the present invention, the at least one ion implantation direction is a plurality of different directions, and an ion implantation process is performed for each direction of the plurality of different directions.

Furthermore, in a method for manufacturing a solid-state image capturing device according to the present invention, the at least one ion implantation direction is a plurality of different directions chosen such that an edge of a tip portion of the impurity region at the surface of the photoelectric conversion section is formed in a manner such that it extends underneath the lower end portion of the gate electrode on the photoelectric conversion section side, and an ion implantation process is performed for each direction of the plurality of different directions.

A method for manufacturing a solid-state image capturing device according to the present invention, in which at least one electric charge detection section detects each respective one of a plurality of electric charges photoelectrically converted and accumulated at photoelectric conversion sections provided on a semiconductor substrate, each electric charge detection section being shared by a plurality of the photoelectric conversion sections, each photoelectric conversion section forming a pixel section of two pixel sections, the at least one electric charge detection section being arranged in a plurality in two dimensions in a unit of the two pixel sections, the method including: an impurity region forming step of forming an impurity region on a surface of each photoelectric conversion section of the plurality of photoelectric conversion sections by performing an ion implantation from at least one direction which corresponds to an arrangement direction of the two pixels, the at least one direction having a predetermined inclination angle with respect to a normal line perpendicular to the surface, wherein the at least one direction of the ion implantation is two directions opposite to each other and the impurity region forming step includes performing an ion implantation process for each direction of the ion implantation, thereby the objective described above being achieved.

A method for manufacturing a solid-state image capturing device according to the present invention, in which at least one electric charge detection section detects each respective one of a plurality of electric charges photoelectrically converted and accumulated at photoelectric conversion sections provided on a semiconductor substrate, each electric charge detection section being shared by a plurality of the photoelectric conversion sections, each photoelectric conversion section forming each pixel section of four pixel sections, at least one electric charge detection section being arranged in two dimensions in a unit of the four pixel sections, the method including: an impurity region forming step of forming an impurity region on a surface of each photoelectric conversion section of the plurality of photoelectric conversion sections by performing an ion implantation from at least one direction which corresponds to an arrangement direction of the four pixels, the at least one direction having a predetermined inclination angle with respect to a normal line perpendicular to the surface, wherein the four pixel sections are formed by two sets of two pixels arranged in upper and lower positions or arranged in left and right positions in a plan view, an arrangement direction of the four pixel sections is a direction from top to bottom or left to right, at least one ion implantation direction is at least two directions opposite to each other, the two directions being either two directions opposite to each other, or another two directions opposite to each other perpendicular to the two directions, and the impurity region forming step includes performing an ion implantation process for each ion implantation direction, thereby the objective described above being achieved.

An electronic information device according to the present invention having a solid-state image capturing device provided in an image capturing section and capable of displaying a captured image information captured by the image capturing section on a display screen, the solid-state image capturing device being manufactured by using the method for manufacturing a solid-state image capturing device described above, thereby the objective described above being achieved.

An electronic information device according to the present invention having a solid-state image capturing device provided in an image capturing section and capable of storing a captured image information captured by the image capturing section in an image storing section, the solid-state image capturing device being manufactured by using the method for manufacturing a solid-state image capturing device described above, thereby the objective described above being achieved.

An electronic information device according to the present invention having a solid-state image capturing device provided in an image capturing section and capable of sending and receiving a captured image information captured by an image section from a communication section, the solid-state image capturing device being manufactured by using a method for manufacturing a solid-state image capturing device described above, thereby the objective described above being achieved.

Preferably, an electric information device according to the present invention performs at least one function capable of: displaying a captured image information on a display screen; storing a captured image information in an image storing section; and sending and receiving a captured image information from a communication section.

These and other advantages of the present invention will become apparent to those skilled in the art upon reading and understanding the following detailed description with reference to the accompanying figures.

### BRIEF DESCRIPTION OF THE DRAWINGS

FIG. 1 is a plan view showing relevant parts of a unit of two pixels of a CMOS-type solid-state image capturing device according to Embodiment 1 of the present invention.

The portion (a) of FIG. 2 is a plan view showing each sectional-position of two pixel sections shown in FIG. 1, the portion (b) of FIG. 2 is a cross-sectional view of the portion (a) of FIG. 2 cut by a line A-A′, and the portion (c) of FIG. 2 is a cross-sectional view of the portion (a) of FIG. 2 cut by a line B-B′.

FIG. 3 is a plan view showing relevant parts in each step for explaining a method for manufacturing the CMOS-type solid-state image capturing device shown in FIG. 1, the portion (a) of FIG. 3 is a plan view showing a step of separating an active region and an inactive region, the portion (b) of FIG. 3 is a plan view showing a step of forming a gate electrode and the portion (c) of FIG. 3 is a plan view showing a step forming a photo diode N layer and a surface P+ layer, and the portion (d) of FIG. 3 is a plan view showing a step of forming an electric charge detection section N layer and a reset drain.

FIG. 4 is a plan view showing: the solid-state image capturing device according to Embodiment 1; and the relationship between a pixel pattern in the solid-state image capturing device and the silicon wafer.

FIG. 5 is a plan view showing relevant parts of a unit of two pixels of a CMOS-type solid-state image capturing device according to Embodiment 2 of the present invention.

The portion (a) of FIG. 6 is a plan view showing each sectional-position of two pixel sections shown in FIG. 5, the portion (b) of FIG. 6 is across-sectional view of the portion (a) of FIG. 6 cut by a line A-A′, the portion (c) of FIG. 6 is a cross-sectional view of the portion (a) of FIG. 6 cut by a line B-B′.

FIG. 7 is a plan view showing relevant parts of a CMOS-type solid-state image capturing device according to Comparison Example 1 of the present invention, in which an electric charge detection section is shared by greater than or equal to three pixel sections.

FIG. 8 is a plan view showing relevant parts of a CMOS-type solid-state image capturing device according to Comparison Example 2 of the present invention, in which an electric charge detection section is shared by greater than or equal to three pixel sections.

FIG. 9 is a plan view showing relevant parts of a unit of four pixels of a CMOS-type solid-state image capturing device according to Embodiment 3 of the present invention.

The portion (a) of FIG. 10 is a plan view showing each sectional-position of four pixel sections shown in FIG. 9, the portion (b) of FIG. 10 is a cross-sectional view of the portion (a) of FIG. 10 cut by a line A-A′, the portion (c) of FIG. 10 is a cross-sectional view of the portion (a) of FIG. 10 cut by a line B-B′, the portion (d) of FIG. 10 is a cross-sectional view of the portion (a) of FIG. 10 cut by a line C-C′, and the portion (e) of FIG. 10 is a cross-sectional view of the portion (a) of FIG. 10 cut by a line D-D′.

FIG. 11 is a plan view showing relevant parts of a unit of four pixels of a CMOS-type solid-state image capturing device according to another example of Embodiment 3 of the present invention.

FIG. 12 is a plan view showing relevant parts of a unit of four pixels of a CMOS-type solid-state image capturing device according to Embodiment 4 of the present invention.

FIG. 13 is a plan view showing relevant parts of a unit of four pixels of a CMOS-type solid-state image capturing device according to another example of Embodiment 4 of the present invention.

The portion (a) of FIG. 14 is a plan view showing each sectional-position of the two pixel sections shown in FIG. 13, the portion (b) of FIG. 14 is a cross-sectional view of the portion (a) of FIG. 14 cut by an A-A′ line, and the portion (c) of FIG. 14 is a cross-sectional view of the portion (a) of FIG. 14 cut by a B-B′ line.

FIG. 15 is a plan view showing relevant parts of a unit of two pixels in a conventional CMOS-type solid-state image capturing device.

The portion (a) of FIG. 16 is a plan view showing each sectional-position of the two pixel sections shown in FIG. 15, the portion (b) of FIG. 16 is a cross-sectional view of the portion (a) of FIG. 16 cut by an A-A′ line, and the portion (c) of FIG. 16 is a cross-sectional view of the portion (a) of FIG. 16 cut by a B-B′ line.

FIG. 17 is a plan view showing relevant parts in each step for explaining a method for manufacturing the CMOS-type solid-state image capturing device shown in FIG. 15, the portion (a) of FIG. 17 is a plan view showing a step of separating an active region and an inactive region, the portion (b) of FIG. 17 is a plan view showing a step of forming a gate electrode and the portion (c) of FIG. 17 is a plan view showing a step forming a photo diode N layer and a surface P+ layer, and the portion (d) of FIG. 17 is a plan view showing a step of forming an electric charge detection section N layer and a reset drain.

FIG. 18 is a view schematically showing potentials formed on each region in a semiconductor substrate so as to correspond to the cross-sectional view of FIG. 16 cut by the line A-A′.

FIG. 19 is a diagram for explaining the effect resulting from the structure, in which an electric charge detection section is shared by each two-pixel section arranged in upper and lower positions as shown in FIG. 15, the portion (a) of FIG. 19 is a plan view showing a unit of two pixels showing a case where the two pixel sections share the electric charge detection section and following sections after the electric charge detection section, and the portion (b) of FIG. 19 is a plan view showing two pixel sections, which shows a case where the electric charge detection section is provided for each pixel.

The portion (a) of FIG. 20 is a plan view showing relevant parts of a unit of two pixels in a conventional CMOS-type solid-state image capturing device, and the portion (b) of FIG. 20 is a cross-sectional view of the portion (a) of FIG. 20 cut by a E-E′ line.

100, 110, 121, 122, 123, 130 CMOS-type solid-state image capturing device

1 N-type semiconductor (silicon) wafer

2 P-type diffusion layer (P well)

5, 51, 52 reading gate electrode

6 reset gate electrode

7, 71, 72 N-type impurity diffusion layer (photoelectric conversion section; electric charge accumulation region)

8, 81 surface P+ layer forming resist pattern

9, 91 electric charge detection section

10 reset drain section

13, 13a, 13b, 13c, 131, 132, 131a, 132a, 131b and 132b photo diode surface P+ layer

14 to 21 ion implantation direction

C1 normal line

These and other advantages of the present invention will become apparent to those skilled in the art upon reading and understanding the following detailed description with reference to the accompanying figures.

### DESCRIPTION OF THE PREFERRED EMBODIMENTS

Hereinafter, the function of the present invention having the aforementioned structure will be described.

In the present invention, at least one electric charge detection section detects each respective one of a plurality of electric charges photoelectrically converted and accumulated at photoelectric conversion sections provided on a semiconductor substrate, each electric charge detection section being shared by a plurality of the photoelectric conversion sections, an impurity region is formed on a surface of each photoelectric conversion section of the plurality of photoelectric conversion sections by performing an ion implantation from at least one direction crossing an arrangement direction of the plurality of photoelectric conversion sections, the at least one direction having a predetermined inclination angle with respect to a normal line perpendicular to the surface.

Therefore, unlike a conventional solid-state image capturing device, there is no co-existence, on a screen, of: the formation of the edge of the tip portion of the impurity region extending under the lower portion of the gate electrode on the photoelectric conversion section side; and the formation of the impurity region away from a predetermined angle with respect to the end portion of the gate electrode on the photoelectric conversion section side by a distance depending on the predetermined angle. As a result, at least one of the above formations is not present. Thus, each positional relationship between the impurity region at the surface of the photoelectric conversion section and the end portion of the gate electrode is uniform or the same. Therefore, the reading characteristic of each pixel section can be uniform or the same, thereby preventing a horizontal streak and display coarseness on a display screen and obtaining an excellent display quality.

As described above, according to the present invention, the impurity region at the surface portion of the photoelectric conversion section is formed such that each positional relationship between the impurity region at the surface portion of the photoelectric conversion section and the edge portion of the gate electrode is uniform or the same. Thus, the reading characteristic of each pixel section can be uniform or the same, thereby preventing a horizontal streak or display coarseness on a display screen and obtaining an excellent display quality.

These and other advantages of the present invention will become apparent to those skilled in the art upon reading and understanding the following detailed description with reference to the accompanying figures.

### DESCRIPTION OF THE PREFERRED EMBODIMENTS

Hereinafter, a case, in which Embodiments 1 to 4 according to the method for manufacturing a solid-state image capturing device according to the present invention are applied to a method for manufacturing a CMOS-type solid-state image capturing device, will be described in detail with reference to the accompanying drawings. Herein, the method for manufacturing a CMOS-type solid-state image capturing device will be described. However, the present invention is not limited to this. The present invention also can be applied to a method for manufacturing a CCD-type solid-state image capturing device.

### Embodiment 1

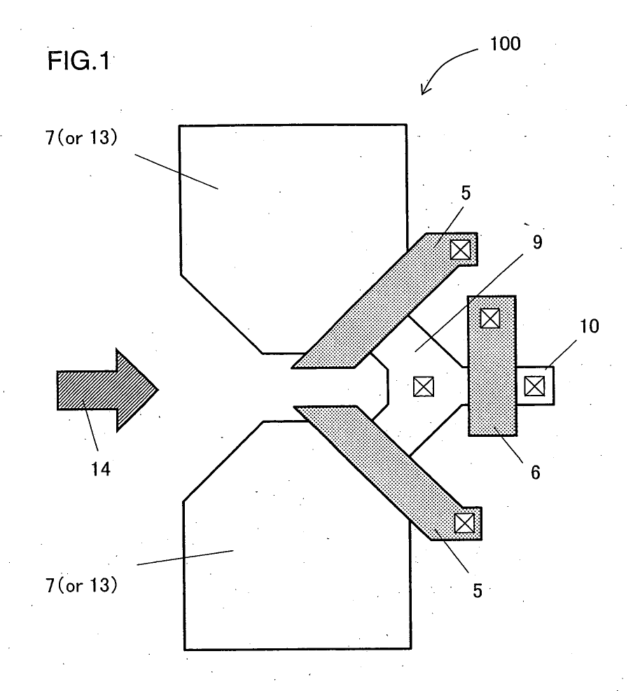

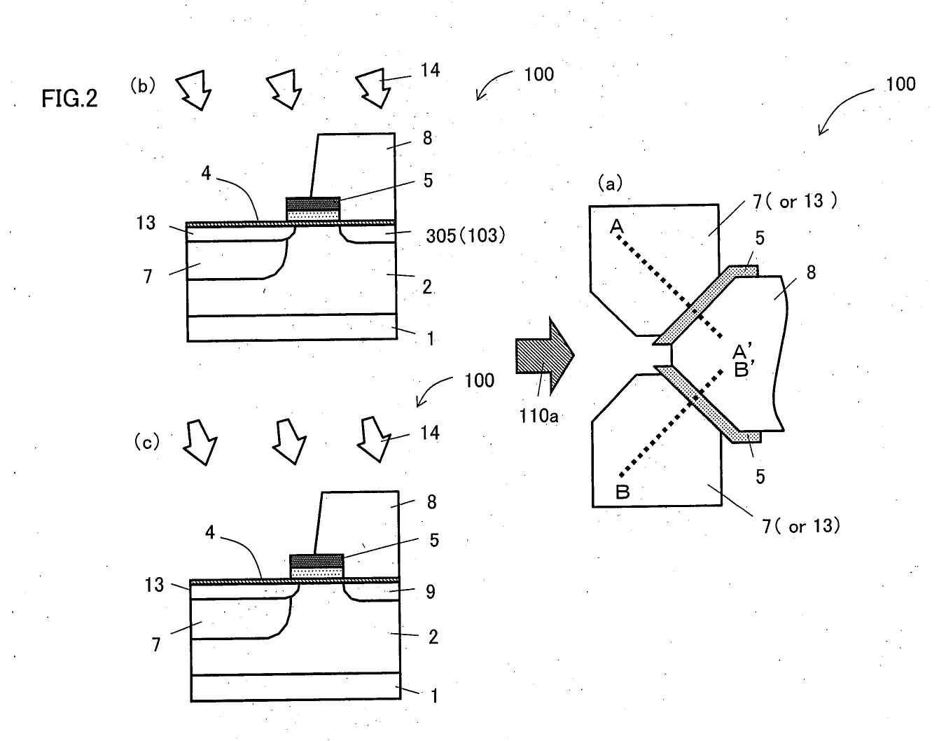

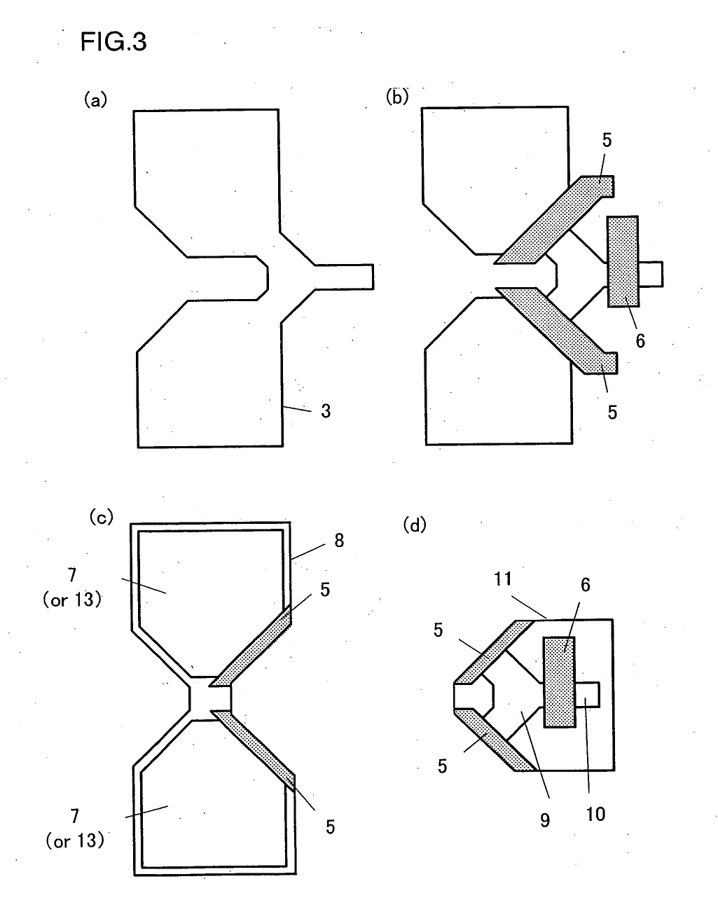

FIG. 1 is a plan view showing relevant parts of a unit of two pixels of a CMOS-type solid-state image capturing device according to Embodiment 1 of the present invention. The portion (a) of FIG. 2 is a plan view showing each sectional-position of two pixel sections shown in FIG. 1. The portion (b) of FIG. 2 is a cross-sectional view of the portion (a) of FIG. 2 cut by a line A-A′. The portion (c) of FIG. 2 is a cross-sectional view of the portion (a) of FIG. 2 cut by a line B-B′. FIG. 3 is a plan view showing relevant parts in each step for explaining a method for manufacturing the CMOS-type solid-state image capturing device shown in FIG. 1.

In FIGS. 1 to 3, a CMOS-type solid-state image capturing devices 100 are arranged in a plurality and two dimensions in a unit of two pixels. One electric charge detection section 9 is shared by the photoelectric conversion sections (N-type impurity diffusion layer 7) via the reading gate electrode 5 of each photoelectric conversion section (photo diode layer; N-type impurity diffusion layer 7) which forms each pixel section of the two pixel sections. The electric charge detection section 9 is provided on an imaginary bisecting line perpendicular to an arrangement direction (alignment direction from top to bottom in the plan view) of the two pixel sections. As described above, the photoelectric conversion sections (photo diode layer; N-type impurity diffusion layer 7), having the electric charge detection section 9 shared thereby, are the two pixel sections arranged in the upper and lower positions in the plan view

A method for manufacturing the CMOS-type solid-state image capturing device 100 according to Embodiment 1 will be described in a unit of two pixel sections.

First, a P-type diffusion layer 2 (P well) is formed on an N-type semiconductor (silicon) substrate 1 by performing an ion implantation (e.g., boron) process and a thermal treatment. Next, in order to separate an active region and an inactive region in an element, an SiN film formed on the substrate is selectively removed only from the inactive region using a pattern 3 as shown in the portion (a) of FIG. 3 in a plan view. A thermal oxidation treatment is performed on the N-type semiconductor substrate. In the thermal oxidation treatment, H₂O is provided in a diffusion hearth at a high temperature of 950 degrees Celsius to 1100 degrees Celsius. As a result, a thick thermal oxide film is formed on the inactive region side.

Next, a gate silicon oxidation film 4 is formed on a surface (surface of the active region) of the silicon substrate 1 by performing a thermal oxidation treatment at a temperature of 1000 degrees Celsius to 1100 degrees Celsius in an atmosphere of O₂ gas and HCI gas. Thereafter, a multi-layered film, in which, for example, a poli-silicon film and a W (tungsten) film are layered, is formed by performing a CVD/sputtering and the like. A photolithography is performed on the multi-layered film using a pattern as shown in the portion (b) of FIG. 3, and then a dry etching is performed on the resultant film. Thus, a reading gate electrode 5 and a reset gate electrode 6 are formed on a region which will become an N-type impurity diffusion layer 7 corresponding to the pattern 3.

Furthermore, the region of the N-type impurity diffusion layer 7 which will become a photo diode layer (photoelectric conversion section; electric charge accumulation region) is patterned by using a surface P+ layer forming resist pattern 8 as shown in the portion (c) of FIG. 3. Thereafter, an ion implantation (e.g., either phosphorus or arsenic) process and a thermal treatment are performed on the resultant N-type impurity diffusion layer 7. Thus, an oxidation film having a thick inactive layer is formed on a circumference of the N-type impurity diffusion layer 7, which will become a photodiode layer. The side of the N-type impurity diffusion layer 7 on the reading gate electrode 5 side is formed in a manner such that it is self-aligned by the reading gate electrode 5.

Furthermore, the electric charge detection section 9 and a reset drain section 10 are each patterned into a predetermined pattern by using an N+ layer forming pattern 11 as shown in the portion (d) of FIG. 3. Thereafter, an ion implantation (e.g., arsenic) process is performed on the resultant electric charge detection section 9 and a reset drain section 10. The electric charge detection section 9 and the reset drain section 10 are formed in a manner such that they are each self-aligned by each of gate electrodes 5 and 5, the reset gate 6 and the oxidation film having a thick inactive region.

Furthermore, in order to suppress a white defect (luminescent spot defect; bright spot on a total black screen) caused by an energy level occurred at the surface (silicon substrate surface) of the photo diode layer, the photo diode layer is patterned by using the same pattern as the surface P+ layer forming resist pattern 8 as shown in the portion (c) of FIG. 3. Anion implantation (e.g., boron) process and a thermal treatment are performed on the surface of the photo diode layer with an ion implantation direction 14 having a predetermined inclination so as to form a photo diode surface P+ layer 13 as an impurity region at the surface of the photoelectric conversion section.

As described above, the CMOS-type solid-state image capturing device 100 according to Embodiment 1 is manufactured.

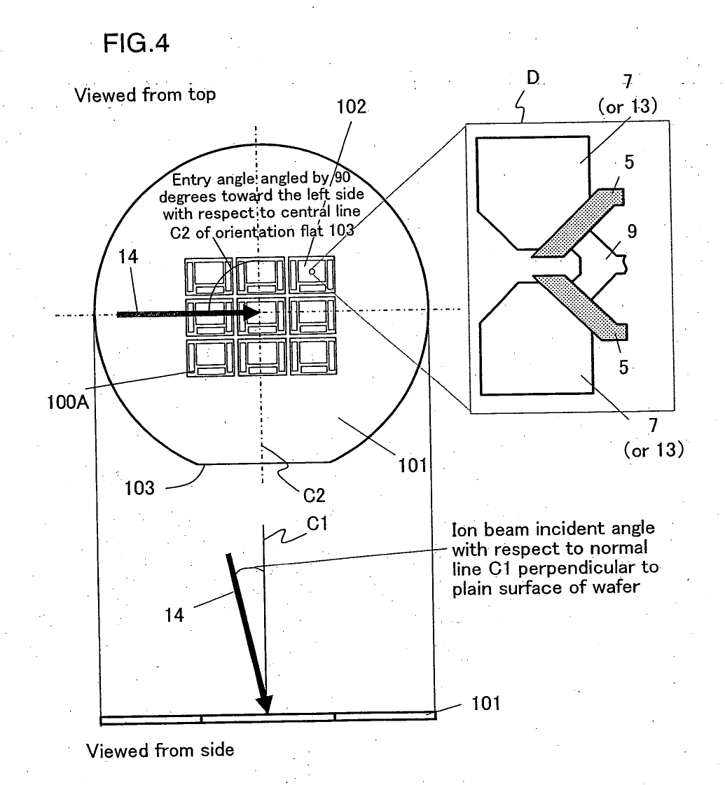

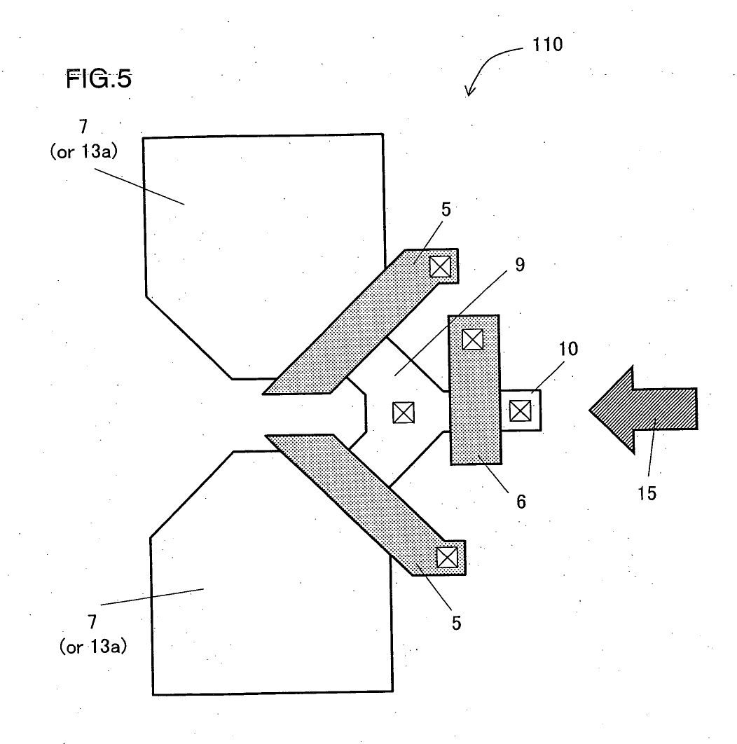

Herein, the relationship between a silicon wafer and a pixel pattern in the solid-state image capturing device 100 according to Embodiment 1 will be described in detail in reference to FIG. 4.

FIG. 4 is a plan view showing: the solid-state image capturing device 100 according to Embodiment 1; and the relationship between a pixel pattern in the solid-state image capturing device 100 and the silicon wafer.

As shown in FIG. 4, the solid-state image capturing devices 100 (image capturing device chip) according to Embodiment 1 undergoes each manufacturing step. Solid-state image capturing devices 100 are only shown at the center of a silicon wafer 101 in order to simplify FIG. 4. However, in fact, the solid-state image capturing devices 100 are arranged on the entire silicon wafer 101.

Image capturing pixel sections are provided in line, in two dimensions, on a pixel area section 102 (image capturing area) of the image capturing device chip 100A. The number of image capturing pixel sections provided range from several hundred thousands to several millions. A partially enlarged view D is an enlarged and retrieved view of a partial image capturing region 102. The partially enlarged view D is an enlarged view showing only photo diode layers (photoelectric conversion section; N-type impurity diffusion layer 7) corresponding to two pixels, the photo diode layers sharing an electric charge detection section 9 via each reading gate electrode 5.

The ion implantation direction 14 of an ion beam used in order to form a photo diode surface P+ layer 13 on the photo diode layer (photoelectric conversion section; N-type impurity diffusion layer 7) has an inclination angle of 7 degrees (±0.5 degrees) with respect to a normal line C1 perpendicular to a plain surface of the silicon wafer 101 as shown in the side view depicted in FIG. 4. The ion implantation direction 14 of the ion beam is a direction (horizontally lateral direction from left to right) angled by 90 degrees toward the left side with respect to a central line C2 of an orientation flat 103 when the orientation flat 103 faces downward as shown from the top depicted in FIG. 4, the orientation flat 103 being a reference of the silicon wafer 101. As described above, the ion implantation direction 14 of the ion beam is three-dimensionally set by an ion implantation device.

In this manner, due to the implantation of an ion beam from the ion implantation direction 14, each positional relationship between the reading gate electrode 5 and the photo diode surface P+ layer 13 can be exactly the same between each respective pixel section arranged in the upper and lower positions. Thus, the tip portion of the photo diode surface P+ layer 13 (impurity region) is formed in a manner such that it extends underneath the end portion of the reading gate electrode 5 on the photo diode surface P+ layer 13 side.

As described above, in Embodiment 1, while the orientation flat 103 of the silicon wafer 101 faces downwards (front side in the figure) an ion beam direction is set such that an ion (e.g., boron) enters from a direction which is inclined by a predetermined angle from the normal line C1, from above and move downward and horizontally from left to right, and the photo diode surface P+ layer 13 is formed so as to extend underneath each reading gate electrode 5. However, the present invention is not limited to this. In the opposite direction to this, i.e., an ion beam direction is set such that an ion (e.g., boron) enters from a direction which is inclined by a predetermined angle from the normal line C1, from above and move downward and horizontally from right to left. This case is shown in the next Embodiment 2.

### Embodiment 2

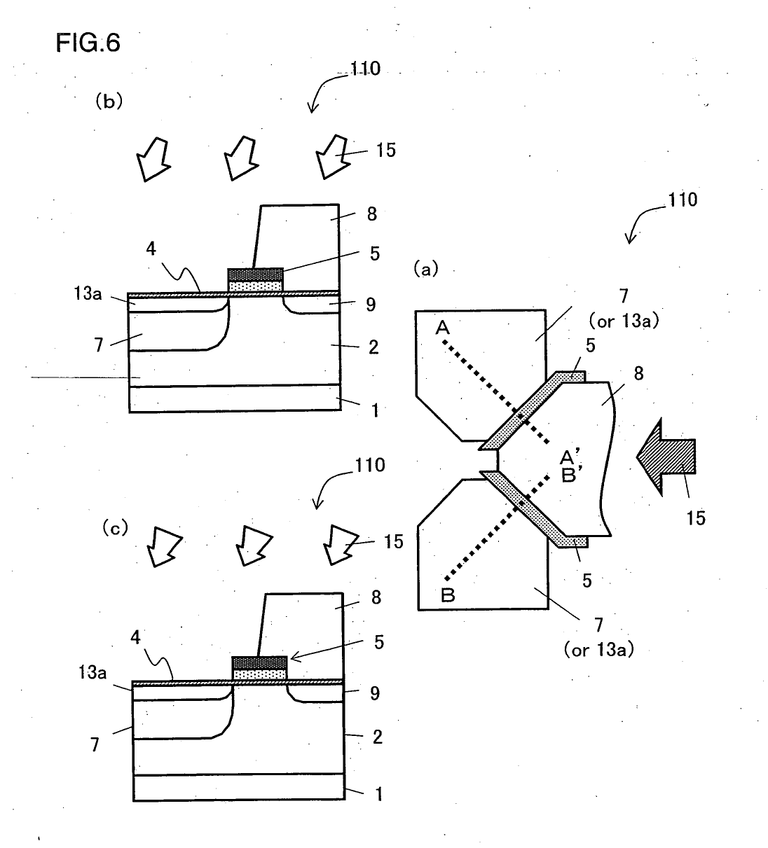

FIG. 5 is a plan view showing relevant parts of a unit of two pixels of a CMOS-type solid-state image capturing device according to Embodiment 2 of the present invention. The portion (a) of FIG. 6 is a plan view showing each sectional-position of two pixel sections shown in FIG. 5. The portion (b) of FIG. 6 is a cross-sectional view of the portion (a) of FIG. 6 cut by a line A-A′. The portion (c) of FIG. 6 is a cross-sectional view of the portion (a) of FIG. 6 cut by a line B-B′.

In FIGS. 5 and 6, a method for manufacturing a CMOS-type solid-state image capturing device 110 according to Embodiment 2 has a difference with the method for manufacturing the CMOS-type solid-state image capturing device 100 according to Embodiment 1 in that an ion implantation (e.g., boron) process from an ion implantation direction 15 having a predetermined inclination and a thermal treatment are performed such that a photo diode surface P+ layer 13a is formed as an impurity region at the surface of a photoelectric conversion section in Embodiment 2. In other words, as described above, the ion implantation direction 15 in Embodiment 2 is inclined in a direction opposite to the ion implantation direction 14 in Embodiment 1.

Ions, which enter from the right side to the left side in FIGS. 5 and 6, are implanted at a position slightly away from the edge of each reading gate electrode 5 due to a shadowing by each reading gate electrode 5. The photo diode surface P+ layer 13a is diffused in a lateral direction due to the following thermal treatment. The edge of the tip portion of the photo diode surface P+ layer 13a is diffused so as to coincide with the edge end of each reading gate electrode 5. In this case, the photo diode surface P+ layer 13a is provided in order to trap energy levels occurred at the surface of the photo diode. If the photo diode layer (photoelectric conversion section; N-type impurity diffusion layer 7) is exposed at the surface of the substrate due to process conditions and the like, the white defect may become aggravated, which is a concern. Thus, it is necessary to carefully set an inclination angle at the time of an ion implantation, an amount of an ion implantation and the like such that the photo diode layer (photoelectric conversion section; N-type impurity diffusion layer 7) is not exposed at the surface of the substrate.

The state of forming a potential barrier underneath each reading gate electrode 5 differs between: the case of the aforementioned Embodiment 1 in which the edge of the tip portion of the photo diode surface P+ layer 13a extends underneath the edge of each reading gate electrode 5; and the case of the present Embodiment 2 in which the edge of the tip portion of the photo diode surface P+ layer 13a coincides with the edge of each reading gate electrode 5. In other words, when the tip of the edge portion of the photo diode surface P+ layer 13 extends underneath the edge of each reading gate electrode 5, the potential barrier is high. When the edge of the tip portion of the photo diode surface P+ layer 13a does not extend underneath but coincides with the edge of each reading gate electrode 5, the potential barrier is low. Thus, caution is required since conditions for: a reading voltage applied to each reading gate electrode 5; and an impurity implantation process underneath each reading gate electrode 5 in order to optimize the capacity of the photo diode are different between when the ion implantation process of an ion beam is performed from left and when the ion implantation process of an ion beam is performed from right.

In the present invention, an electric charge detection section 9 can be shared by greater than or equal to three pixel sections. Herein, a case for this will be described in the next Comparison Example 1.

### COMPARISON EXAMPLE 1

In the present Comparison Example 1, a case in which greater than or equal to three pixel sections (photo diode layer) share one charge electric section will be described.

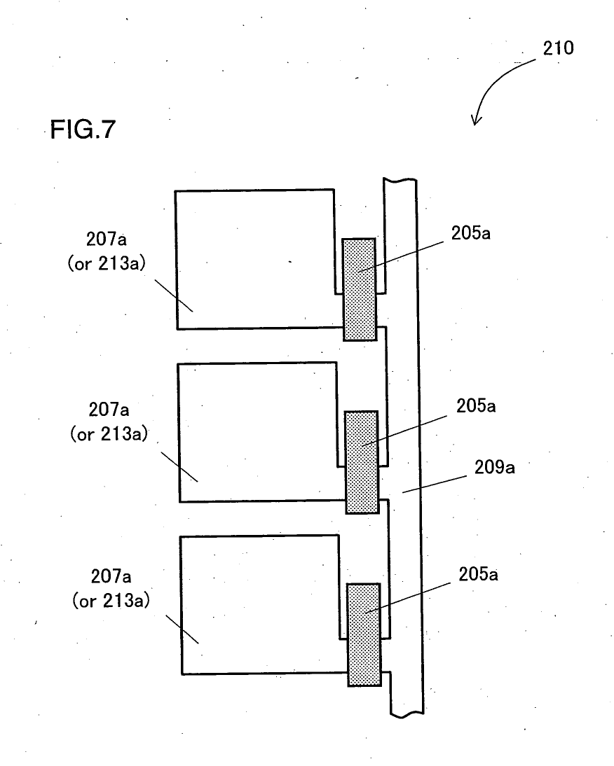

FIG. 7 is a plan view showing relevant parts of a CMOS-type solid-state image capturing device according to Comparision Exmple 1 of the present invention, in which an electric charge detection section 209 is shared by greater than or equal to three pixel sections.

As shown in FIG. 7, in the CMOS-type solid-state image capturing device 210 according to the present Comparison Example 1, greater than or equal to three pixel sections (photo diode layer 207a) which are arranged in a longitudinal direction share one electric charge detection section 209a via a reading gate electrode 205a of each pixel section.

However, it is necessary to extend a metal wiring pattern to the full length of the electric charge detection section 209a, to which the metal wiring pattern is connected and over which all of the pixel sections are arranged, all the pixel sections sharing the pattern of the electric charge detection section 209a. Thus, if a layout in which the electric charge detection section 209a is connected by the metal wiring pattern or the like is not large enough, the effect of increase in the photo diode region is not obtained. The greater the number of sharing pixel sections increases, the faster and more complicated the drive for each pixel section becomes. Therefore, the number of sharing pixel sections in the aforementioned Embodiments 1 and 2 is “2”.

### COMPARISON EXAMPLE 2

In the present Comparison Example 2, a case in which four pixel sections arranged in longitudinal and lateral directions (photo diode layer) share one charge electric section will be described.

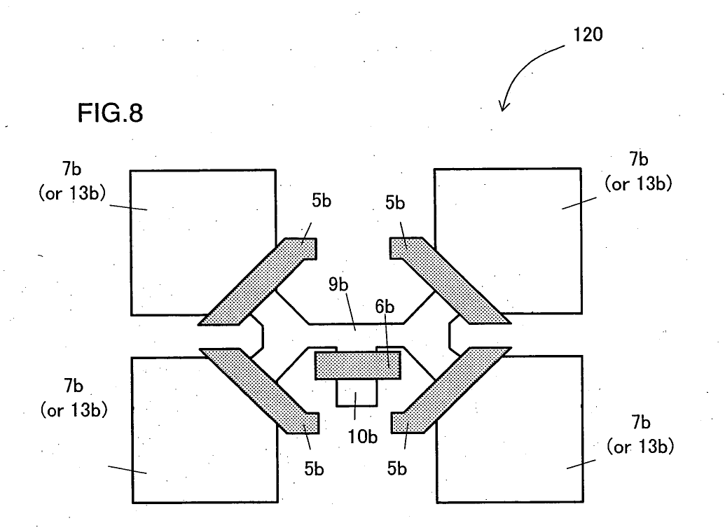

FIG. 8 is a plan view showing a case in which four pixel sections are arranged in longitudinal and lateral directions in a CMOS-type solid-state image capturing device according to Comparison Example 2 of the present invention.

As shown in FIG. 8, in the CMOS-type solid-state image capturing device 120 in the present Comparison Example 2, four pixel sections (photo diode layer 7b) which are arranged in the longitudinal and lateral directions share one electric charge detection section 9b via a reading gate electrode 5b of each pixel section.

In this manner, a layout can be provided in which the four pixel sections share one electric charge detection section 9a. In this case, when an ion implantation process is performed on the two pixel sections arranged on the right side in the longitudinal direction from an ion beam direction (direction horizontally from left in the aforementioned Embodiment 1) in a manner such that the edge of the tip portion of photo diode surface P+ layer 13b extends underneath the edge of each reading gate electrode 5b, the edge of the tip portion of the photo diode surface P+ layer 13c coincides with the edge of each reading gate electrode 5c in two pixel sections arranged on the left side in the longitudinal direction (direction horizontally from right in the aforementioned Embodiment 2). Thus, the characteristic of the two pixel sections arranged on the left side in the longitudinal direction and the characteristic of the two pixel sections arranged on the right side in the longitudinal direction are different from each other. Although a horizontal streak does not appear on a display screen, display coarseness occurs, and the CMOS-type solid-state image capturing device 120 can not be used when the display coarseness occurs. An example to solve this problem is shown in Embodiment 3.

### Embodiment 3

In Embodiment 3, in the case of four pixel sections arranged in longitudinal and lateral directions, a case is described in which an ion beam implantation process is performed for each direction of the ion implantation direction 14 (Embodiment 1) and the ion implantation direction 15 (Embodiment 2) in two steps, each ion implantation direction having a predetermined inclination.

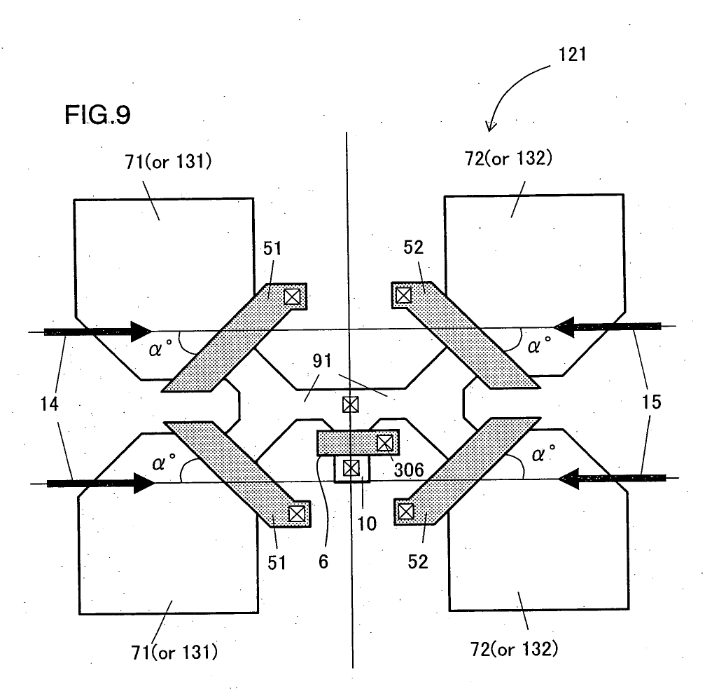

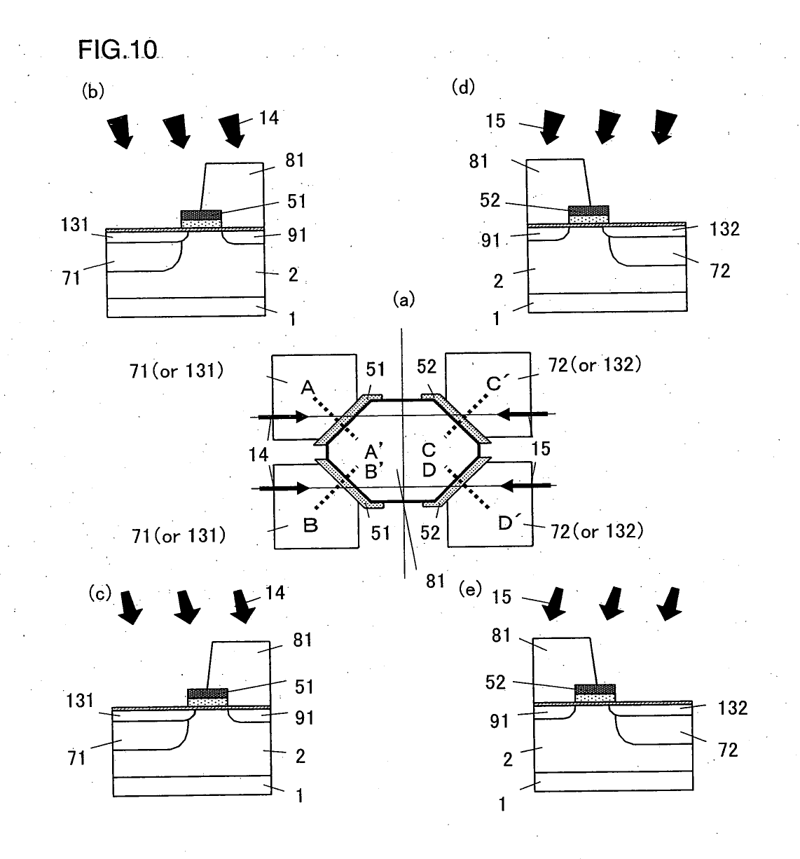

FIG. 9 is a plan view showing relevant parts of a unit of four pixels, which are arranged in longitudinal and lateral directions, of a CMOS-type solid-state image capturing device according to Embodiment 3 of the present invention. The portion (a) of FIG. 10 is a plan view showing each sectional-position of four pixel sections shown in FIG. 9. The portion (b) of FIG. 10 is a cross-sectional view of the portion (a) of FIG. 10 cut by a line A-A′. The portion (c) of FIG. 10 is a cross-sectional view of the portion (a) of FIG. 10 cut by a line B-B′. The portion (d) of FIG. 10 is a cross-sectional view of the portion (a) of FIG. 10 cut by a line C-C′. The portion (e) of FIG. 10 is a cross-sectional view of the portion (a) of FIG. 10 cut by a line D-D′.

As shown in FIGS. 9 and 10, in four pixel sections, which are arranged in longitudinal and lateral directions, having: an N-type impurity diffusion layer 71 (photo diode surface P+ layer 131) of each of two pixels, respectively, arranged in upper and lower positions on the left side, which will become photo diode layers (photoelectric conversion section; electric charge accumulation region); and an N-type impurity diffusion layer 72 (photo diode surface P+ layer 132) of each of two pixels, respectively, arranged in upper and lower positions on the right side, which will become photo diode layers (photoelectric conversion section; electric charge accumulation region), an electric charge detection section 91 is provided at the center of the four pixel sections via each respective gate electrode 51 and 52 of the N-type impurity diffusion layers 71 and 72 so as to be shared by the four pixel sections. The electric charge detection section 91 can be connected to a reset drain section 10 via a reset gate electrode 6. The reference numeral 81 shows a resist pattern at the time of implanting ions into regions which will become the photo diode surface P+ layers 131, 132

An ion implantation process is performed with an implantation time being divided by two. While an orientation flat of the silicon wafer faces downwards (front side in the figure), an ion beam direction is set such that an ion (e.g., boron) enters from an ion implantation direction which is inclined by a predetermined angle with respect to the aforementioned normal line C1, from above and move downward and from horizontally from left to right in the figure. An ion implantation process is performed such that the two photo diode surface P+ layers 131 arranged in the upper and lower positions on the left side extend underneath each respective reading gate electrode 51 of the photo diode surface P+ layers 131. Thereafter, in a direction opposite to this, i.e., an ion beam direction is set such that an ion (e.g., boron) enters from an ion implantation direction which is inclined by a predetermined angle with respect to the aforementioned normal line C1, from above and moved downward and horizontally from right to left in the figure. An ion implantation process is performed such that the two photo diode surface P+ layers 132 arranged in the upper and lower positions on the right side extend underneath each respective reading gate electrode 52 of the photo diode surface P+ layers 132. Thereby, even in the case of four pixel sections arranged in the longitudinal and lateral directions, the reading characteristics of the four pixel sections arranged in the longitudinal and later directions can be uniform to each other.

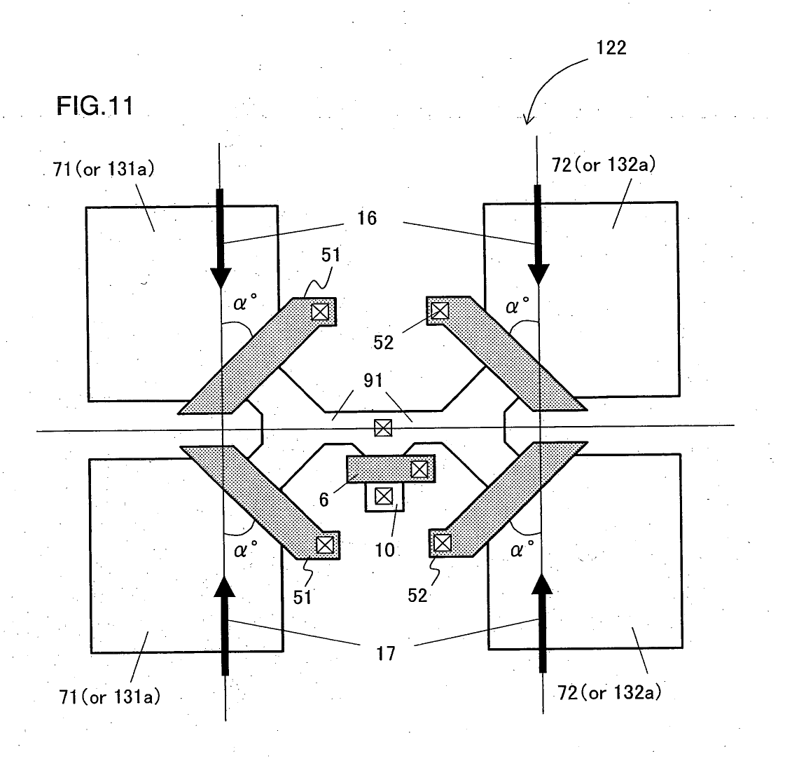

In Embodiment 3, the ion implantation directions 14 horizontally from left to right are first ion entry directions into the photo diode surface P+ layers 131 and 132 and the ion implantation directions 15 horizontally from right to left are second ion entry directions into the photo diode surface P+ layers 131 and 132. However, the ion directions are not limited to these. As shown in FIG. 11, ion implantation directions 16 vertically from top to bottom in the figure are first ion entry directions 16 into the photo diode surface P+ surface layers 131 and 132 and ion implantation directions 17 vertically from bottom to top in the figure are second ion entry directions 17 into the photo diode surface P+ surface layers 131 and 132. Even in this case, an effect similar to the one resulting from Embodiment 3 can be obtained.

An ion implantation process is performed with an implantation time being divided by two. While an orientation flat of the silicon wafer faces downwards (front side in the figure), an ion beam direction is set such that ions (e.g., boron) enter from an ion implantation direction which is inclined by a predetermined angle with respect to the aforementioned normal line C1, from above and move downward and vertically from top to bottom in the figure. Ion implantation process is performed such that the two photo diode surface P+ layers 131a and 132a arranged in upper position on the left and right sides extend underneath each respective reading gate electrode 51 and 52 of the photo diode surface P+ layers 131a and 132a. Thereafter, in a direction opposite to this, i.e., an ion beam direction is set such that ions (e.g., boron) enter from an ion implantation direction which is inclined by a predetermined angle with respect to the aforementioned normal line C1, from above and move downward and vertically from bottom to top in the figure. An ion implantation process is performed such that the two photo diode surface P+ layers 131a and 132a arranged in the lower position on the left and right sides extend underneath each respective reading gate electrode 51 and 52 of the photo diode surface P+ layers 131a and 132a. Therefore, even in the case of four pixel sections arranged in the longitudinal and lateral directions, the reading characteristics of the four pixel sections arranged in the longitudinal and later directions can be uniform to each other.

### Embodiment 4

In Embodiment 4, in the case of four pixel sections arranged in longitudinal and lateral directions, a case in which an ion implantation process is sequentially performed for each ion implantation direction of an ion beam in four steps will be described.

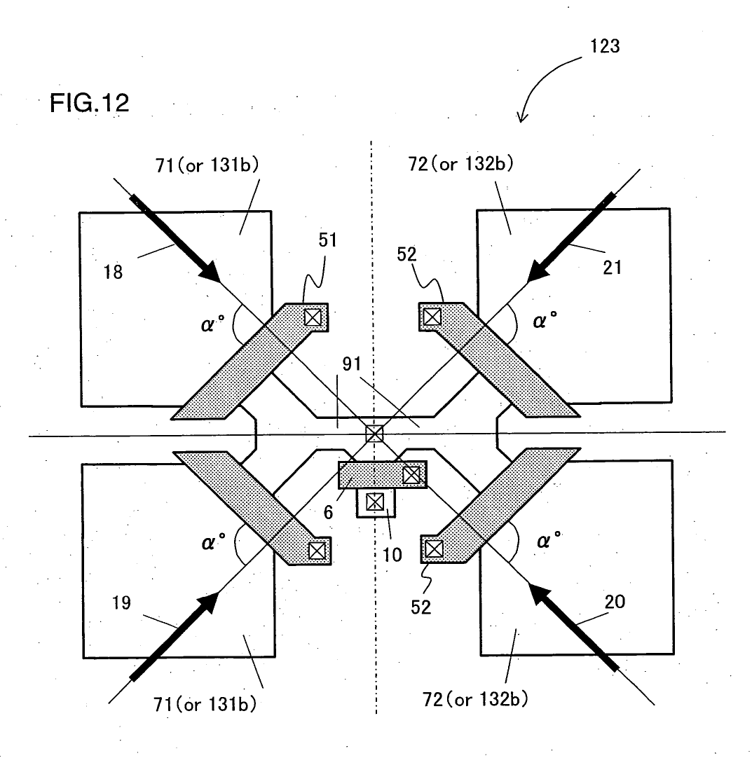

FIG. 12 is a diagram showing relevant parts of a unit of four pixel sections arranged in longitudinal and lateral directions of a CMOS-type solid-state image capturing device according to Embodiment 4 of the present invention.

An ion implantation process is performed with an implantation time being divided by four. While an orientation flat faces downwards (front side in the figure), an ion implantation direction 18 of an ion beam is set such that an ion (e.g., boron) enters from an implantation direction which is inclined by a predetermined angle with respect to the aforementioned normal line C1, from above and move downward vertical to the figure and from a direction forming an angle of 45 degrees from the side between directly left and directly top to the side between directly right to directly bottom (a direction perpendicular to a longitudinal direction of the reading gate electrode 51), as shown in FIG. 12. An ion implantation process is performed such that the photo diode surface P+ layer 131b arranged in the upper position on the left side extends underneath the reading gate electrode 51 adjacent to the photo diode surface P+ layer 131b arranged in the upper position on the left side. An ion implantation direction 19 of an ion beam direction (ion beam implantation direction) is set such that ions (e.g., boron) enter from an implantation direction which is inclined by a predetermined angle with respect to the aforementioned normal line C1, from above to below vertical to the figure and from a direction forming an angle of 45 degrees from the side between directly left and directly bottom to the side between directly right to directly top (a direction perpendicular to a longitudinal direction of the reading gate electrode 51). An ion implantation process is performed such that the photo diode surface P+ layer 131b arranged in the lower position on the left side extends underneath the reading gate electrode 51 adjacent to the photo diode surface P+ layer 131b arranged in the lower position on the left side. Furthermore, an ion implantation direction 20 of an ion beam is set such that ions (e.g., boron) enter from an implantation direction which is inclined by a predetermined angle with respect to the aforementioned normal line C1, from above to below vertical to the figure and from a direction forming an angle of 45 degrees from the side between directly right and directly bottom to the side between directly left to directly top (a direction perpendicular to a longitudinal direction of the reading gate electrode 51). An ion implantation process is performed such that the photo diode surface P+ layer 132b arranged in the lower position on the right side extends underneath the reading gate electrode 52 adjacent to the photo diode surface P+ layer 132b arranged in the lower position on the right side. Furthermore, an ion implantation direction 21 of an ion beam is set such that ions (e.g., boron) enter from an implantation direction which is inclined by a predetermined angle with respect to the aforementioned normal line C1, from above to below vertical to the figure and from a direction forming an angle of 45 degrees from the side between directly right and directly top to the side between directly left to directly bottom (a direction perpendicular to a longitudinal direction of the reading gate electrode 52). An ion implantation process is performed such that the photo diode surface P+ layer 132b arranged in the upper position on the right side extends underneath the reading gate electrode 52 adjacent to the photo diode surface P+ layer 132b arranged in the upper position on the right side. An ion implantation process is performed with an implantation time being divided by four. Therefore, even in the case of four pixel sections arranged in the longitudinal and lateral directions, the reading characteristics of the four pixel sections arranged in the longitudinal and later directions can be uniform to each other.

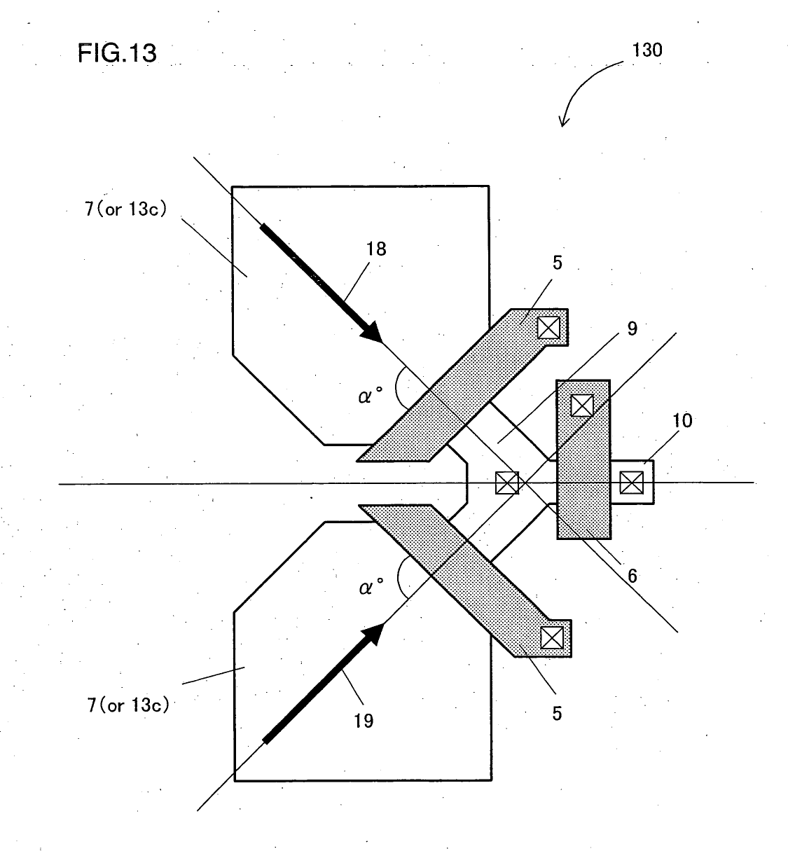

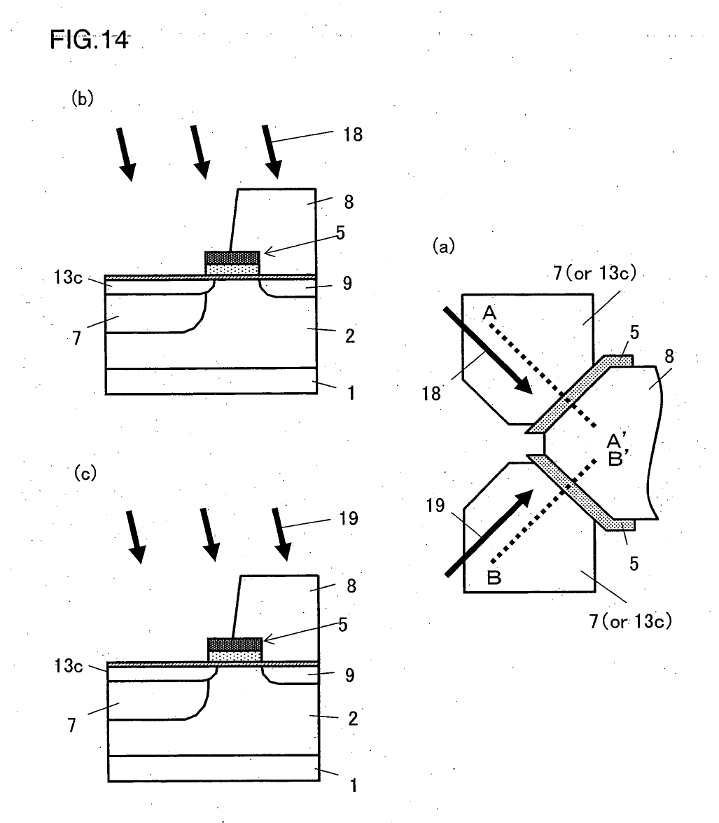

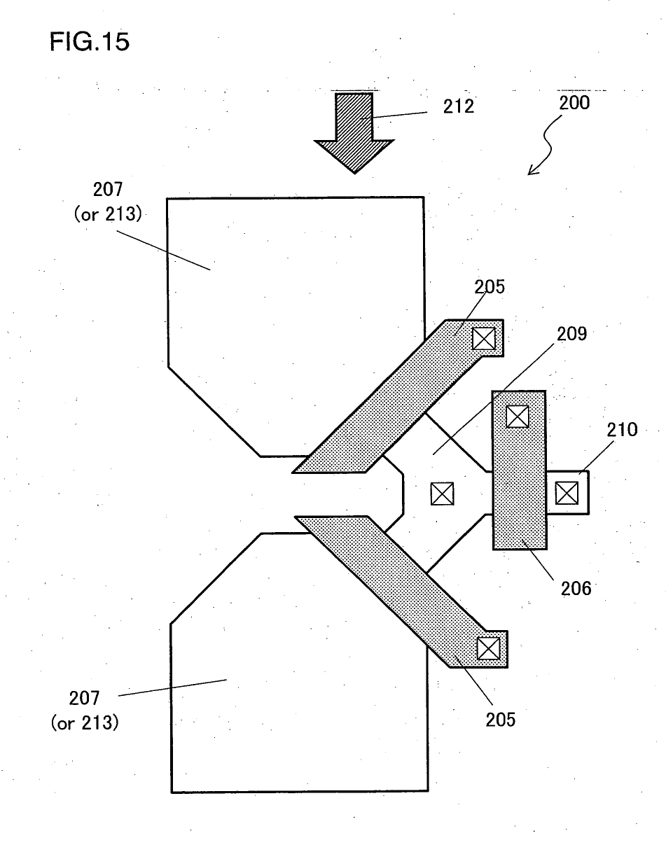

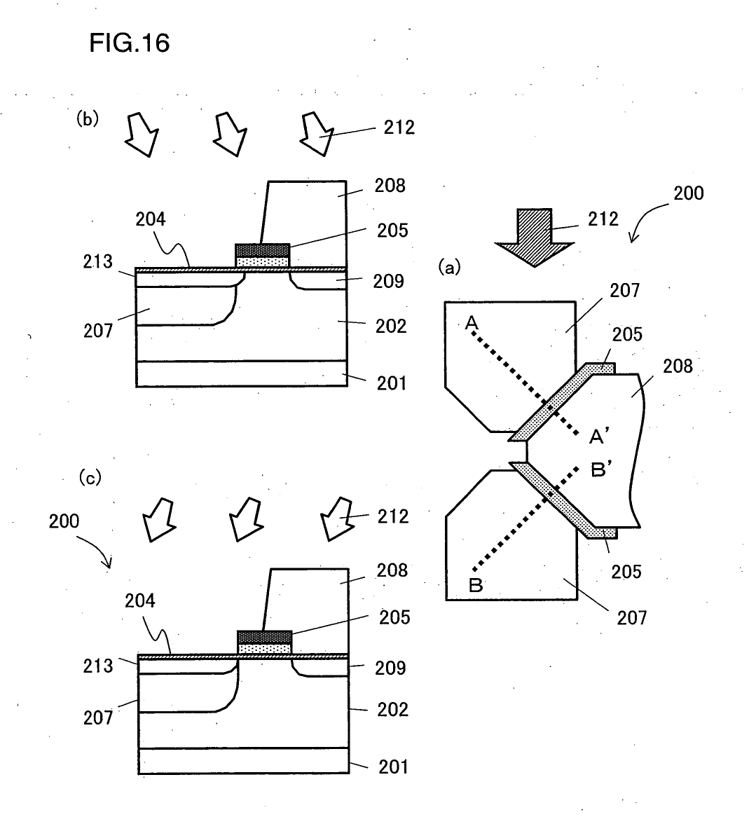

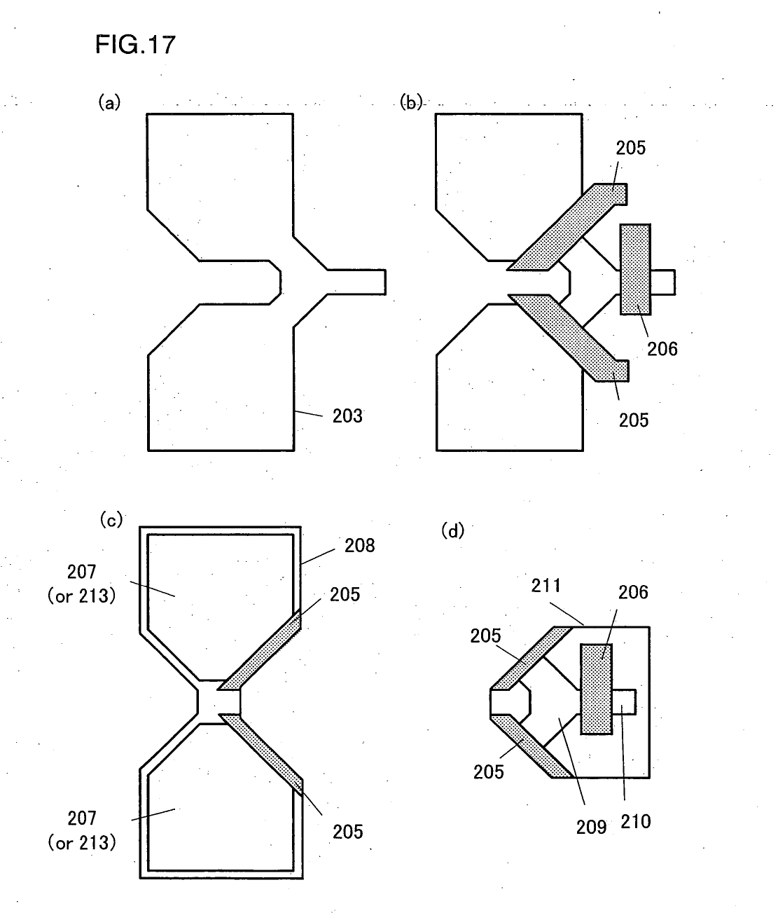

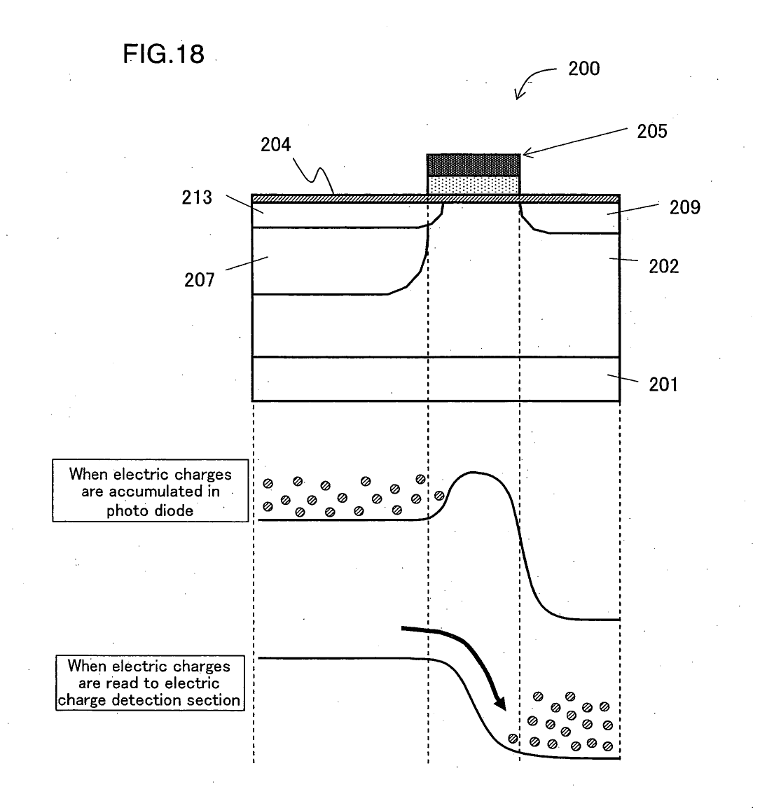

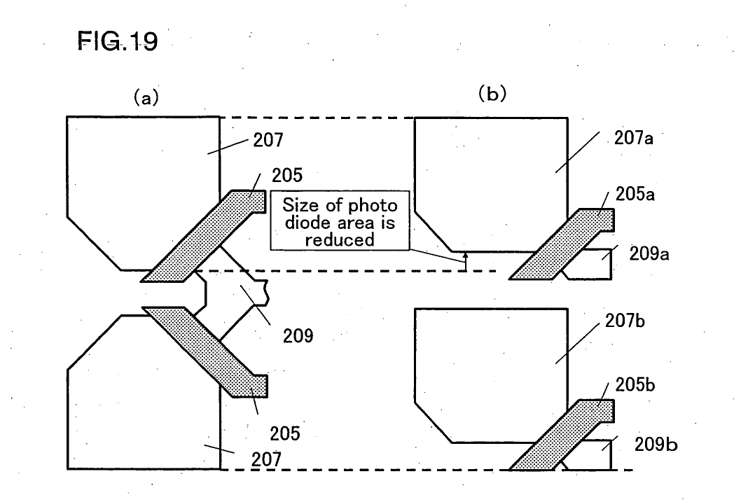

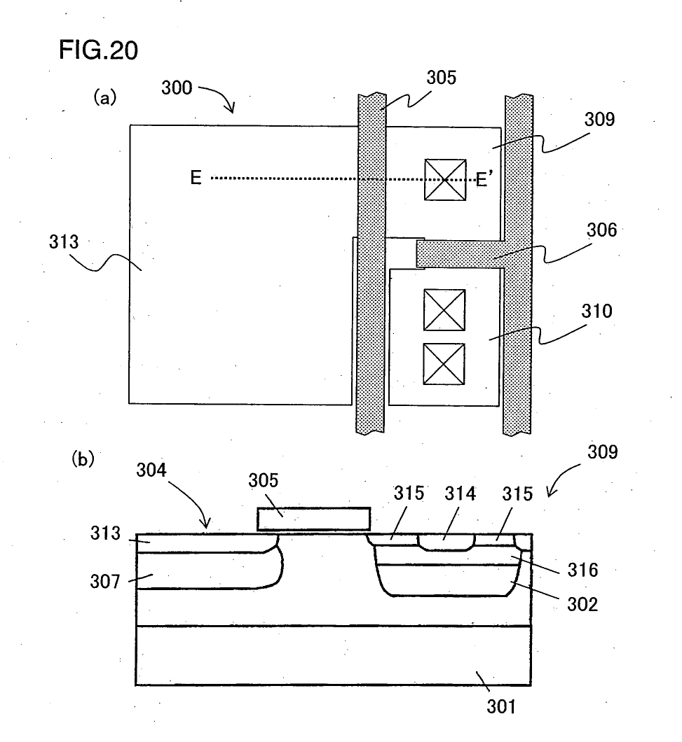

In Embodiment 4, in the case where one electric charge detection section 91 is shared by four pixel sections arranged in the longitudinal and lateral directions as shown in FIG. 12, a case, in which an ion implantation process is sequentially performed for each implantation direction of the ion beam in four steps, has been described. However, the present invention is not limited to this. In the case in which the ion implantation directions 18 and 19 are the same as those in the case shown in FIG. 12 and the electric charge detection section 9 is shared by two pixel sections arranged in the upper and lower positions as shown in FIGS. 13 and 14, an ion implantation process can be sequentially performed on the photo diode surface P+ layer 13c for each ion implantation direction of an ion beam in two steps. In this case, the angle α between the ion implantation directions 18 and 19 and the respective reading gate electrodes 5 is 90 degrees or approximately 90 degrees.

In the figures described above, the members which have the same functions are denoted by the same numerals.

As described above, according to Embodiments 1 to 4, in a method for manufacturing a solid-state image capturing device, in which at least one electric charge detection section 9 detects each respective one of a plurality of electric charges photoelectrically converted and accumulated at two N-type impurity diffusion layers (photoelectric conversion sections) arranged in the upper and lower positions or four N-type impurity diffusion layers arranged in the longitudinal and lateral directions on a semiconductor substrate, each electric charge detection section being shared by: a unit of two pixels of two N-type impurity diffusion layers (photoelectric conversion sections) arranged in the upper and lower positions; or a unit of four pixels four N-type impurity diffusion layers arranged in the longitudinal and lateral directions, the method includes: an impurity region forming step of forming an impurity region on a surface of each photoelectric conversion section of the plurality of photoelectric conversion sections by performing an ion implantation from at least one direction being perpendicular to an arrangement direction of the plurality of photoelectric conversion sections, the at least one direction having a predetermined inclination angle with respect to a normal line perpendicular to the surface. Therefore, each positional relationship between a reading gate and a photo diode surface P+ layer at each pixel section of two pixels sections arranged in the upper and lower positions or four pixel section arranged in the longitudinal and lateral directions can be uniform or the same. Thus, the pixel characteristic (reading voltage, capacity of photo diode) of each pixel section of the two pixels sections arranged in the upper and lower positions or the four pixel sections arranged in the longitudinal and lateral directions can be uniform or the same, thereby preventing a horizontal streak or display coarseness on a display screen and obtaining the display screen with an excellent display quality.

Furthermore, in the present invention, as similar to aforementioned Reference 2, if the positional relationship between the N-type impurity diffusion layer and the photo diode surface P+ layer is adjusted such that an optimal overlap of the N-type impurity diffusion layer and the photo diode surface P+ layer is formed, electric charges can be completely transferred to the electric charge detection section without residual electric charge, thereby suppressing the occurrence of residual image.

In Embodiments 1 to 4, the ion implantation process is performed so as to have approximately 7 degrees (±0.5 degrees) of a beam inclination angle with respect to a normal line C1 perpendicular to a plain surface of the wafer at the time of implanting ions into the photo diode surface P+ layer. The reason that the ion beam inclination angle is approximately 7 degrees is that a channeling does not occur within an ion crystal lattice of a wafer surface at this degree. Herein, a commonly-used ion implantation process which is conventionally performed with approximately 7 degrees of beam entry angle is applied to the present invention as conventionally employed. In a case when it is preferred that a profile of ion implantation is slightly adjusted depending on conditions of the silicon lattice, there is no problem even if other beam inclination angles rather than 7 degrees is used.

In Embodiment 1 to 4, no specific description has been given. However, an electronic information device (e.g., a camera-equipped cellular phone and a digital camera) can be obtained by employing the solid-state image capturing device according to Embodiments 1 to 4, the electronic information device having a display screen with an excellent display quality and a horizontal streak and display coarseness being prevented due to the effect of the present invention. In the electronic information device, the solid-state image capturing device manufactured by using a method for manufacturing the solid-state image capturing device according to the present invention is provided in an image capturing section. Thus, it is possible to display a captured image information captured by the image capturing section on a display screen of a display section and also possible to store the captured image information captured by the image capturing section in an image storing section. Furthermore, it is possible to send and receive the captured image information captured by the image capturing section from a communication section. The electronic information device according to the present invention only needs to include at least one of the display section, the image storing section and the communication section.

Furthermore, in Embodiments 1 to 4, no specific description has been given. However, an end face of the gate electrode on the photoelectric conversion section side has a tapered shape widening toward the bottom when viewed in a cross-sectional view, and the gate electrode is tapered at a predetermined inclination angle (7 degrees ±0.5 degrees) such that the impurity region (photo diode surface P+ layer) at the surface is not formed away by the predetermined inclination angle from the end portion of the gate electrode on the photoelectric conversion section side.

Furthermore, in Embodiments 1 to 4, in the case where the photoelectric conversion sections are two pixel sections arranged in upper and lower positions adjacent to each other, an ion implantation direction is one of: a direction (e.g., left to right) perpendicular to the arrangement direction of the two pixel sections in a plan view; and a direction (right to left) opposite to this direction. In the case of four pixels in which two sets of the two pixel sections arranged in upper and lower positions arranged in left and right sides, ion implantation directions are two directions, one direction being perpendicular to the arrangement direction of the four pixel sections in a plan view and the other direction of the two directions being opposite to this direction. Furthermore, in the case of two pixels arranged in the upper and lower positions adjacent to each other, the ion implantation directions are two directions forming an angle of 45 degrees with respect to the direction perpendicular to the arrangement direction in a plan view. Furthermore, in the case of four pixel sections in which two sets of the two pixel sections arranged in the upper and lower sections are arranged in the left and right sides, the ion implantation directions are four directions, two directions of the four directions forming an angle of 45 degrees with respect to the direction perpendicular to the arrangement direction in a plan view, and the other two directions of the four directions being opposite to the two directions. The present invention is not limited to this. In other words, the present invention only needs to include an impurity region forming step of forming an impurity region on a surface of each photoelectric conversion section of the plurality of photoelectric conversion sections by performing an ion implantation from at least one direction crossing an arrangement direction of the plurality of photoelectric conversion sections, the at least one direction having a predetermined inclination angle with respect to a normal line perpendicular to the surface. The present invention only needs to include an impurity region forming step of forming an impurity region on each surface of the plurality of photoelectric conversion sections by performing an ion implantation from two directions, one of the two directions being one arrangement direction of the plurality of photoelectric conversion sections and the other of the two directions being opposite to the one arrangement direction, the two directions having a predetermined inclination angle with respect to a normal line perpendicular to the surface.

As described above, the present invention is exemplified by the use of its preferred Embodiments 1 to 4. However, the present invention should not be interpreted solely based on Embodiments 1 to 4 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 4 of the present invention. Furthermore, it is understood that any patent, any patent application and any references cited in the present specification should be incorporated by reference in the present specification in the same manner as the contents are specifically described therein.

### INDUSTRIAL APPLICABILITY

In the field of: a method for manufacturing a solid-state image capturing device in which an electric charge detection section is shared by each plurality of photoelectric conversion sections, the electric charge detection section detecting an amount of electric charges converted from incident light by the photoelectric conversion sections; and an electronic information device (e.g., a camera-equipped cellular phone, a digital-still camera and a digital video camera) using the solid-state image capturing device manufactured by using the manufacturing method, the pixel characteristic of each pixel section can be uniform or the same, thereby preventing a horizontal streak or display coarseness on a display screen and obtaining the display screen with an excellent display quality.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A method for manufacturing a solid-state image capturing device, in which at least one electric charge detection section detects each respective one of a plurality of electric charges photoelectrically converted and accumulated at photoelectric conversion sections provided on a semiconductor substrate, each electric charge detection section being shared by a plurality of the photoelectric conversion sections, the method comprising:
an impurity region forming step of forming an impurity region on a surface of each photoelectric conversion section of the plurality of photoelectric conversion sections by performing an ion implantation from at least one direction crossing an arrangement direction of the plurality of photoelectric conversion sections, the at least one direction having a predetermined inclination angle with respect to a normal line perpendicular to the surface.

2. A method for manufacturing a solid-state image capturing device according to claim 1, wherein an angle between the arrangement direction and the at least one direction which crosses the arrangement direction is 90 degrees.

3. A method for manufacturing a solid-state image capturing device according to claim 1, wherein an angle between the arrangement direction and the at least one direction which crosses the arrangement direction is 45 degrees.

4. A method for manufacturing a solid-state image capturing device according to claim 1, wherein the at least one direction which crosses the arrangement direction is a plurality of directions.

5. A method for manufacturing a solid-state image capturing device according to claim 1, wherein the plurality of photoelectric conversion sections is two pixel sections, and the at least one ion implantation direction is either a direction perpendicular to the arrangement direction in a plan view or a direction opposite to the direction perpendicular to the arrangement direction in the plan view.

6. A method for manufacturing a solid-state image capturing device according to claim 5, wherein the electric charge detection section is shared by the two pixel sections via the reading gate electrode of each pixel section, the electric charge detection section being provided on an imaginary bisecting line perpendicular to an arrangement direction of the two pixel sections.

7. A method for manufacturing a solid-state image capturing device according to claim 1, wherein the plurality of photoelectric conversion sections is four pixel sections, and the at least one ion implantation direction is two directions, the two directions being a direction perpendicular to the arrangement direction in a plan view and a direction opposite to the direction perpendicular to the arrangement direction in the plan view.

8. A method for manufacturing a solid-state image capturing device according to claim 7, wherein the four pixel sections include two sets of two pixel sections arranged in upper and lower positions or arranged in left and right positions in a plan view, and the electric charge detection section shared by the four pixel sections is provided at a central position of the four pixel sections via the reading gate electrode of each pixel section.

9. A method for manufacturing a solid-state image capturing device according to claim 1, wherein the plurality of photoelectric conversion sections is two pixel sections, and the at least one ion implantation direction is two directions, the two directions forming an angle of 45 degrees with respect to the direction perpendicular to the arrangement direction in a plan view.

10. A method for manufacturing a solid-state image capturing device according to claim 9, wherein the electric charge detection section is shared by the two pixel sections via the reading gate electrode of each pixel section, the electric charge detection section being provided on an imaginary bisecting line perpendicular to an arrangement direction of the two pixel sections.

11. A method for manufacturing a solid-state image capturing device according to claim 1, wherein the plurality of photoelectric conversion sections is four pixel sections, and the at least one ion implantation direction is four directions in total, two directions of the four directions forming an angle of 45 degrees with respect to the direction perpendicular to the arrangement direction in a plan view, and the other two directions of the four directions being provided opposite to the two directions.

12. A method for manufacturing a solid-state image capturing device according to claim 11, wherein the four pixel sections include two sets of two pixel sections arranged in upper and lower positions or left and right positions in a plan view, and the electric charge detection section shared by the four pixel sections is provided at a central position of the four pixel sections via the reading gate electrode of each pixel section.

13. A method for manufacturing a solid-state image capturing device according to claim 1, comprising
a gate electrode forming step of forming a gate electrode on a semiconductor substrate which is of a conductivity-type, for reading a plurality of electric charges from the photoelectric conversion section to the electric charge detection section;
a photoelectric conversion section forming step of forming an electric charge accumulation region of a first conductivity-type as the photoelectric conversion section; and
an electric charge detection section forming step of forming the electric charge detection section of the first conductivity-type, the electric charge detection section being adjacent to the photoelectric conversion section with a gate electrode interposed therebetween;
wherein the impurity region forming step includes forming the impurity region on the surface of the photoelectric converstion section, the impurity region being formed to be of a second conductivity-type.

14. A method for manufacturing a solid-state image capturing device according to claim 13, wherein the at least one ion implantation direction is chosen such that an edge of a tip portion of the impurity region is formed in a manner such that it extends underneath a lower end portion of the gate electrode on the photoelectric conversion section side.

15. A method for manufacturing a solid-state image capturing device according to claim 13, wherein the at least one ion implantation direction is chosen such that it forms a predetermined angle with respect to the end portion of the gate electrode on the photoelectric conversion section side, and the impurity region is formed away from the end portion of the gate electrode by a distance depending on the predetermined angle.

16. A method for manufacturing a solid-state image capturing device according to claim 13, wherein an end face of the gate electrode on the photoelectric conversion section side has a tapered shape widening toward the bottom when viewed in a cross-sectional view, and the gate electrode is tapered at the predetermined inclination angle such that the impurity region at the surface is not formed away by the predetermined inclination angle from the end portion of the gate electrode on the photoelectric conversion section side.

17. A method for manufacturing a solid-state image capturing device according to claim 13, wherein the at least one ion implantation direction is chosen to cross a longitudinal direction of the gate electrode with respect to the longitudinal direction from the photoelectric conversion section side and forms an angle α with respect to the longitudinal direction of the gate electrode.

18. A method for manufacturing a solid-state image capturing device according to claim 17, wherein the angle α is 90 degrees or 45 degrees.

19. A method for manufacturing a solid-state image capturing device according to claim 13, wherein the at least one ion implantation direction is a plurality of different directions chosen such that an edge of a tip portion of the impurity region at the surface of the photoelectric conversion section is formed in a manner such that it extends underneath the lower end portion of the gate electrode on the photoelectric conversion section side, and an ion implantation process is performed for each direction of the plurality of different directions.

20. A method for manufacturing a solid-state image capturing device according to claim 1, wherein the plurality of electronic conversion sections having the electric charge detection section shared thereby is two pixel sections arranged in upper and lower positions or arranged in left and right positions in a plan view.

21. A method for manufacturing a solid-state image capturing device according to claim 20, wherein the electric charge detection section is shared by the two pixel sections via the reading gate electrode of each pixel section, the electric charge detection section being provided on an imaginary bisecting line perpendicular to an arrangement direction of the two pixel sections.

22. A method for manufacturing a solid-state image capturing device according to claim 1, wherein the plurality of photoelectric conversion sections having the electric charge detection section shared thereby is four pixel sections.

23. A method for manufacturing a solid-state image capturing device according to claim 22, wherein the four pixel sections include two sets of two pixel sections arranged in upper and lower positions or arranged in left and right positions in a plan view, and the electric charge detection section shared by the four pixel sections is provided at a central position of the four pixel sections via the reading gate electrode of each pixel section.

24. A method for manufacturing a solid-state image capturing device according to claim 1, wherein the predetermined inclination angle is an angle at which a channeling does not occur within a crystal lattice of the semiconductor substrate.

25. A method for manufacturing a solid-state image capturing device according to claim 24, wherein the semiconductor substrate is a silicon semiconductor substrate, and the crystal lattice is a silicon crystal lattice.

26. A method for manufacturing a solid-state image capturing device according to claim 24, wherein the predetermined inclination angle is 7 degrees ±0.5 degrees.

27. A method for manufacturing a solid-state image capturing device according to claim 1, wherein the at least one ion implantation direction is a plurality of different directions, and an ion implantation process is performed for each direction of the plurality of different directions.

28. A method for manufacturing a solid-state image capturing device, in which at least one electric charge detection section detects each respective one of a plurality of electric charges photoelectrically converted and accumulated at photoelectric conversion sections provided on a semiconductor substrate, each electric charge detection section being shared by a plurality of photoelectric conversion sections, the method comprising:
an impurity region forming step of forming an impurity region on each surface of the plurality of photoelectric conversion sections by performing an ion implantation from two directions, one of the two directions being one arrangement direction of the plurality of photoelectric conversion sections and the other of the two directions being opposite to the one arrangement direction, the two directions having a predetermined inclination angle with respect to a normal line perpendicular to the surface.

29. A method for manufacturing a solid-state image capturing device according to claim 28, comprising
a gate electrode forming step of forming a gate electrode on a semiconductor substrate which is of a conductivity-type, for reading a plurality of electric charges from the photoelectric conversion section to the electric charge detection section;
a photoelectric conversion section forming step of forming an electric charge accumulation region of a first conductivity-type as the photoelectric conversion section; and
an electric charge detection section forming step of forming the electric charge detection section of the first conductivity-type, the electric charge detection section being adjacent to the photoelectric conversion section with a gate electrode interposed therebetween;
wherein the impurity region forming step includes forming the impurity region on the surface of the photoelectric conversion section, the impurity region being formed to be of a second conductivity-type.

30. A method for manufacturing a solid-state image capturing device according to claim 28, wherein the plurality of electronic conversion sections having the electric charge detection section shared thereby is two pixel sections arranged in upper and lower positions or arranged in left and right positions in a plan view.

31. A method for manufacturing a solid-state image capturing device according to claim 30, wherein the electric charge detection section is shared by the two pixel sections via the reading gate electrode of each pixel section, the electric charge detection section being provided on an imaginary bisecting line perpendicular to an arrangement direction of the two pixel sections.

32. A method for manufacturing a solid-state image capturing device according to claim 28, wherein the plurality of photoelectric conversion sections having the electric charge detection section shared thereby is four pixel sections.

33. A method for manufacturing a solid-state image capturing device according to claim 32, wherein the four pixel sections include two sets of two pixel sections arranged in upper and lower positions or arranged in left and right positions in a plan view, and the electric charge detection section shared by the four pixel sections is provided at a central position of the four pixel sections via the reading gate electrode of each pixel section.

34. A method for manufacturing a solid-state image capturing device according to claim 28, wherein the predetermined inclination angle is an angle at which a channeling does not occur within a crystal lattice of the semiconductor substrate.

35. A method for manufacturing a solid-state image capturing device according to claim 34, wherein the semiconductor substrate is a silicon semiconductor substrate, and the crystal lattice is a silicon crystal lattice.

36. A method for manufacturing a solid-state image capturing device according to claim 34, wherein the predetermined inclination angle is 7 degrees ±0.5 degrees.

37. A method for manufacturing a solid-state image capturing device according to claim 28, wherein the at least one ion implantation direction is a plurality of different directions, and an ion implantation process is performed for each direction of the plurality of different directions

38. A method for manufacturing a solid-state image capturing device, in which at least one electric charge detection section detects each respective one of a plurality of electric charges photoelectrically converted and accumulated at photoelectric conversion sections provided on a semiconductor substrate, each electric charge detection section being shared by a plurality of the photoelectric conversion sections, each photoelectric conversion section forming a pixel section of two pixel sections, the at least one electric charge detection section being arranged in a plurality in two dimensions in a unit of the two pixel sections, the method comprising:
an impurity region forming step of forming an impurity region on a surface of each photoelectric conversion section of the plurality of photoelectric conversion sections by performing an ion implantation from at least one direction which corresponds to an arrangement direction of the two pixels, the at least one direction having a predetermined inclination angle with respect to a normal line perpendicular to the surface,
wherein the at least one direction of the ion implantation is two directions opposite to each other and the impurity region forming step includes performing an ion implantation process for each direction of the ion implantation.

39. A method for manufacturing a solid-state image capturing device, in which at least one electric charge detection section detects each respective one of a plurality of electric charges photoelectrically converted and accumulated at photoelectric conversion sections provided on a semiconductor substrate, each electric charge detection section being shared by a plurality of the photoelectric conversion sections, each photoelectric conversion section forming each pixel section of four pixel sections, at least one electric charge detection section being arranged in two dimensions in a unit of the four pixel sections, the method comprising:
an impurity region forming step of forming an impurity region on a surface of each photoelectric conversion section of the plurality of photoelectric conversion sections by performing an ion implantation from at least one direction which corresponds to an arrangement direction of the four pixels, the at least one direction having a predetermined inclination angle with respect to a normal line perpendicular to the surface,
wherein the four pixel sections are formed by two sets of two pixels arranged in upper and lower positions or arranged in left and right positions in a plan view, an arrangement direction of the four pixel sections is a direction from top to bottom or left to right, at least one ion implantation direction is at least two directions opposite to each other, the two directions being either two directions opposite to each other, or another two directions opposite to each other perpendicular to the two directions, and the impurity region forming step includes performing an ion implantation process for each ion implantation direction.

40. An electronic information device having a solid-state image capturing device provided in an image capturing section and capable of displaying a captured image information captured by the image capturing section on a display screen, the solid-state image capturing device being manufactured by using the method for manufacturing a solid-state image capturing device according to claim 1.

41. An electronic information device according to claim 40 capable of storing a captured image information captured by the image capturing section in an image storing section.

42. An electronic information device according to claim 40 capable of sending and receiving a captured image information captured by the image capturing section from a communication section.

43. An electronic information device having a solid-state image capturing device provided in an image capturing section and capable of storing a captured image information captured by the image capturing section in an image storing section, the solid-state image capturing device being manufactured by using the method for manufacturing a solid-state image capturing device according to claim 1.

44. An electronic information device according to claim 43 capable of displaying a captured image information captured by the image capturing section on a display screen.

45. An electronic information device according to claim 43 capable of sending and receiving a captured image information captured by the image capturing section from a communication section.

46. An electronic information device having a solid-state image capturing device provided in an image capturing section and capable of sending and receiving a captured image information captured by an image section from a communication section, the solid-state image capturing device being manufactured by using a method for manufacturing a solid-state image capturing device according to claim 1.

47. An electronic information device according to claim 46 capable of displaying a captured image information captured by the image capturing section on a display screen.

48. An electronic information device according to claim 46 capable of storing a captured image information captured by the image capturing section in an image storing section.
